(19) United States
(12) Patent Application Publication
(10) Pub. No.: US 2015/0236723 A1
(43) Pub. Date: Aug. 20, 2015

(54) Parallel VLSI architectures for constrained turbo block convolutional decoding

(71) Applicant: Eric Morgan Dowling, Escazu (CR)

(72) Inventor: Eric Morgan Dowling, Escazu (CR)

(21) Appl. No.: 13/999,376

(22) Filed: Feb. 19, 2014

(51) Int. Cl. H03M 13/29; H03M 13/27

(52) U.S. Cl. CPC H03M 13/2933; H03M 13/2951; H03M 13/2792

(57) ABSTRACT

A constrained turbo block convolutional code (CTBC) involves a serial concatenation of a outer block code B with an inner recursive convolutional code, joined together by a constrained interleaver type 2 (CI-2). The CI-2 interleaver is designed off line, and prior to VLSI design time. The present invention provides massively parallel systems, methods, and apparatus for use in CTBC encoding and decoding. For example, a massively parallel CTBC decoder is be implemented using N processors, each with local private memory, and each with local access to a one or more respective memory locations (e.g., registers) in one or more respective multiported memory banks that each hold extrinsic or related information used in CTBC code iterative SISO decoding. Both the arithmetic decoding operations and the CI-2 interleaving and deinterleaving functions are performed in parallel using the systems, methods, and apparatus of the present invention.

### BACKGROUND OF THE INVENTION

1. Field of the Invention

This invention relates generally to communication encoders, decoders, transmitters, receivers, and systems. More particularly, aspects of the invention relate to a massively parallel VLSI architecture for iterative decoders that decode serial concatenations involving an outer block code and an inner recursive convolutional code coupled together by a constrained interleaver with a fixed, predetermined, pseudo-randomized permutation function that is designed to maintain a target minimum hamming distance.

2. Description of the Related Art

The prior art includes U.S. Pat. No. 8,537,919 “Encoding and decoding using constrained interleaving,” and its continuation-in-part, U.S. Pat. No. 8,532,209, “Methods, apparatus and systems for coding with constrained interleaving, and both of these US patents are incorporated herein by reference in order to provide the reader with written description level details of the related encoder/decoder structures as known in the prior art. In this patent application, some terms are defined differently than the US patents incorporated by reference herein. Therefore, it is to be understood that the interpretation of terms used in the claims herein should be taken in the context of the present application and not the references incorporated herein. The prior art also includes J. Fonseka, E. Dowling, S. I. Han and Y. Hu, “Constrained interleaving of serially concatenated codes with inner recursive codes,” IEEE Communications Letters, Vol. 17, No. 7, July 2013, referred to herein as “the Fonseka [1] reference.” The prior art also includes J. Fonseka, E. Dowling, T. Brown and S. I. Han, “Constrained interleaving of turbo product codes,” IEEE Communications Letters, vol. 16, 2012, pp. 1365-1368, September 2012, referred to herein as “the Fonseka [2] reference.” The above-listed patents and technical publications also cite to related articles in the technical literature and to other U.S. Patent references, which are also part of the prior art.

Consider FIG. 1, which corresponds to FIG. 4 in U.S. Pat. Nos. 8,537,919 and 8,532,209. FIG. 1 shows an encoder structure that can represent a method and/or an apparatus for encoding in accordance with what is called herein a “constrained turbo block convolutional” (CTBC) code. The CTBC encoder embodiment of FIG. 1 makes use of an outer block code (OBC) encoder 405, that encodes in accordance with a selected OBC. For example the OBC can be a (n, k) block code, B, where n>k and n, k are positive integers. The message bit stream at the input can be considered to be a sequence of k-bit blocks consisting of message bits. Each k-bit message block is first processed by the OBC encoder 405 which, in the exemplary embodiment of FIG. 1, encodes according to an (n, k) outer code with minimum Hamming distance (MHD) given by MHD=d₀. A characterizing feature of the embodiment of FIG. 1 is that it also makes use of an inner recursive convolutional code (IRCC) encoder 415 that encodes its input bit stream in accordance with an inner recursive convolutional code (the selected IRCC). An appropriate IRCC is chosen to have an MHD given by MHD=dᵢ. For example, the IRCC, could be selected to be a rate-1 accumulator given by G(D)=1/(1+D). Another specific example of an IRCC is to use the rate-1 accumulator followed by a (λ,λ,−1) SPC encoder (or any other block code), or any other recursive convolutional code (RCC). The combination of the accumulator followed by the (λ,λ−1) SPC encoder provides a 4-state IRCC. The value of λ can be chosen to provide design flexibility to chose the IRCC to fine tune the rate and/or the dᵢ value to design a CTBC code to meet a particular set of design specifications. In this patent application, the “RCC” can refer to any recursive convolutional code, while IRCC specifically refers to an RCC that is used as an inner code in a CTBC code or a similar serially concatenated code where the RCC is used as the inner code.

Another characterizing feature of the CTBC encoder 400 is that it makes use of a constrained interleaver 410. Any specific CTBC code is defined in terms of the specifically selected outer block code B used in the OBC encoder 405, the specifically selected recursive convolutional code (RCC) used in the IRCC encoder 415, and the exact interleaver size and permutation function used to define a specific embodiment of the constrained interleaver 410. The constrained interleaver 410, and various forms of its interleaver constraints are described in the above-cited prior art references. The constrained interleaver 410 can be designed to provide an interleaver gain, G₁, similar to uniform interleaving, but also can be designed to ensure that the net MHD of the entire CTBC code satisfies MHD≧d₀dᵢ. It can be noted that if the CI-2 used in the CTBC were to be replaced by a uniform interleaver of the same length, a “Uniform-interleaved Turbo Block Convolutional” (UTBC) code would result, and the MHD of this corresponding UTBC code would typically be close to MHD

Various forms of constrained interleavers are defined in the above-referenced US patents and the Fonseka references [1] and [2]. The above-referenced US Patents teach how interleaver constraints can be defined to design the constrained interleaver 410 to enforce the property MHD>d₀dᵢ. In U.S. Pat. No. 8,532,209, the term and notation “Constrained interleaver type 2” and its abbreviation “CI-2” is introduced to refer to constrained interleavers that exhibit the property MHD>d₀dᵢ. Such CI-2s use inter-row constraints in order to achieve MHD>d₀dᵢ. The Fonseka [1] reference provides additional analysis that proves that the use of the inter-row constraints introduced in the above-referenced US Patents can be used to achieve MHDs in the range of d₀dᵢ≦MHD≦d₀²dᵢ. The CI-2's interleaver gain is approximately the same as the interleaver gain provided by the uniform interleaver.

Note that the constrained interleaver block 410 in FIG. 1 is labeled “r×ρn constrained interleaver.” This is because, as discussed in the above-referenced US patents, the constrained interleaver's permutation function is designed using a r×ρn matrix structure. Herein, this r×ρn matrix structure is instead referred to as an “L×ρn constrained interleaver design matrix.” That is, while the above-referenced US Patents use the symbol r to denote the number of rows used in the constrained interleaver design matrix, in this patent application the symbol L is used to denote the number of rows used in the constrained interleaver design matrix. Also, the terminology “constrained interleaver design matrix” is used herein instead of “constrained interleaver matrix” in order to more specifically call out the fact that the L×ρn constrained interleaver design matrix is used to define the CI-2 permutation function at design time. Because the CI-2 permutation function has a unique inverse permutation function, the above mentioned CI-2 design process actually designs a CI-2 permutation function and inverse permutation function pair. The constrained interleaver design matrix is a mathematical construct and need not be explicitly implemented at run time. At run time, all a decoder needs to perform is the CI-2 permutation function and inverse permutation function pair. At run time the constrained interleaver 410 can be implemented as a specific instance of a uniform interleaver whose permutation function is fixed in accordance with a particular predetermined pseudorandom sequence, where the specific pseudorandom sequence is selected according to the CI-2 design method using the L×ρn constrained interleaver design matrix. CI-2 de-interleaving can performed at run time using a uniform interleaver that operates in accordance with the predetermined CI-2 inverse permutation function.

At this point let us pause to review a specific preferred version of the CI-2 design rules as explained in U.S. Pat. No. 8,537,919, and U.S. Pat. No. 8,532,209 the Fonseka [1] reference. The CI-2 design algorithm below is able to achieve the MHD advantages as discussed above by avoiding low distance error events from occurring at the output of the constrained interleaver. The CI-2 design algorithm achieves this, in part, by using inter-row constraints. In general, the assignment of coded bits on any i^{th} row can be made dependent up to lₘₐₓ number of previous rows. In this structure, due to the cyclic nature of feeding bits into the inner code by going back to the first row after the L^{th} row, the placement of bits on any (L−i)^{th} row (i<lₘₐₓ) depends not only on the lₘₐₓ, previous rows and also on the first (lₘₐₓ−i) rows. The inter-row constraints ensure that coded bits on lₘₐₓ different adjacent rows (modulo L) share no more than κ(l) common columns, where l=1, 2 . . . , lₘₐₓ. One way to generate the CI-2 design matrix (for example as can be optionally used in block 705 of FIG. 7) is to follow the following steps. 1) Start by placing ρ pseudorandomly selected codewords of the outer code B on the first row and uniformly interleave all ρn bits. 2) For rows l<i≦(L−lₘₐₓ), DO: (i) pseudorandomly select ρ codewords of the outer code B from the remaining codewords and pseudo randomize the coded bits of each pseudorandomly selected separately; (ii) psuedorandomly place the first kₗ=minₗ(kₗ) coded bits of all ρ codewords on the i^{th} row. (iii) When placing the k^{th} (kₗ<k≦n) coded bit of any s^{th} (1≦s≦ρ) codeword: (a) for each l=1, 2, . . . , lₘₐₓ (or applicable), search for codewords on the (i−1)^{th} row that share κ(l) columns with already placed (k−1) coded bits of the j^{th} codeword on the i^{th} row; (b) If such codeword/codewords are found, remove all n columns occupied by them. (c) Psuedorandomly select a column among the remaining columns for the k^{th} coded bit. And 3) for rows (L−lₘₐₓ)<i<L, DO: Follow the steps in 2) above, but modify step (i) and (ii) to include searching for codewords on the (l−L+1)^{th} row (because column k on the i^{th} row corresponds to column (k+1) on the (l−L+1)^{th} row).

The output bit stream of the constrained interleaver 410 is fed to the IRCC encoder 415 which encodes a message sequence in accordance with the IRCC, which has a corresponding minimum distance that is denoted MHD=dᵢ. The constrained interleaver 410 can also be viewed as a permutation function that operates on a vector of Lρn bits where n is defined as above, L corresponds to the number or rows in the constrained interleaver design matrix, and ρ corresponds to the number of n-bit codewords of the outer code B that are placed on each row of the constrained interleaver design matrix. Conceptually, the permutation operation implemented by the constrained interleaver 410 can be viewed in terms of reading the coded bits out of the columns of the (L×ρn) constrained interleaver design matrix in column-major order. The output of the constrained interleaver is coupled to the IRCC encoder 415. That is, the constrained-interleaved bits are fed into the IRCC encoder 415 and the output of the IRCC encoder 415 is a valid coded sequence of the CTBC code.

The CTBC coded output bits from the block 415 are next fed to a mapper 420.

The mapper 420 maps one or more bits onto a constellation symbol. For example, the mapper 420 can map each single bit onto a corresponding binary phase shift keyed (BPSK) constellation point, or can map pairs of bits onto a corresponding quadrature phase shift keyed (QPSK) constellation point (or a differentially encoded—DQPSK constellation point), or can map sets of three bits each onto an 8-PSK constellation point, or can map sets of four bits onto a 16-quadrature amplitude modulated (16-QAM) constellation point (or 16-DQAM constellation point), etc.

Next consider FIG. 2, which corresponds to FIG. 5 in U.S. Pat. Nos. 8,537,919 and 8,532,209. FIG. 2 shows a prior art receiver method and apparatus for a receiver 500 used to receive and decode a signal r(t) which was generated in accordance with FIG. 1 or any of its variants or equivalents. Although in U.S. Pat. Nos. 8,537,919 and 8,532,209 the receiver 500 can optionally be configured to decode turbo product encoded signals, in the present patent application, it is assumed that the receiver 500 is used to receive and decode a CTBC encoded signal as discussed above in connection with FIG. 1. Block 505 processes or otherwise demodulates a received signal r(t) to generate an initial vector rₛ, which preferably corresponds to a vector of bit metrics. As is known in the art, a bit metric is a logarithm of a ratio defined by the probability that a given bit is a one divided by the probability the same bit is a zero. At the receiver, in block 505, for each respective bit position (in case of 16-QAM there are 4 bits per symbol) the receiver will first find the minimum distance from the i^{th} bit position of the received signal point, r(t) (at a sample instant) to the closest constellation point that has 1 in the respective bit position, d₁ (closest distance to 1). Next the receiver will find the minimum distance from the i^{th} bit position of the received signal point, r(t) to the constellation point that has 0 in the respective bit position, d₀ (closest distance to 0). The receiver 505 will then preferably compute the log bit metric as (d₁−d₀)*SNR. The length of the vector rₛ is M_{CTBC}=Lρn. Note that if the mapper 420 maps according to a non-binary modulation such as QAM, each non-binary symbol will preferably be de-mapped to a given set of bits, each of which will be represented by their respective bit metrics in the vector rₛ. The bit metrics are preferably used in decoding of the component codes using an a-posteriori probability (APP) decoding technique.

The portion of the receiver 500 minus the demodulator block 505 can be considered to illustrate a decoder method and/or apparatus that may be integrated into the receiver system 500. For example, one or more VLSI chips can be used to implement the block 505 while one or more other VLSI chips can be used for the rest of the blocks 510-535. In such embodiments, the receiver 500 minus any channel interface demodulator front end portion of the block 505 is referred to as the decoder 500 herein.

The receiver 500 is preferably configured as follows. The receiver block 505 can include any combination of a demodulator, signal conditioning, and bit detector of any variety, to include a soft bit detector that provides bit metrics as are known in the art. The output of the block 505 couples to an IRCC soft in soft out (SISO) decoder 515 for soft decoding and to a constrained deinterleaver 510. It is noted that the deinterleaving operation 510 need only be performed on the first iteration of this decoding process because the sequence rₛ does not change from one iteration to the next during CTBC code SISO iterative decoding 500, and the rₛ metrics information is reused by both the IRCC SISO decoder and/or an OBC SISO decoder 525 during OBC SISO decoding.

Throughout this patent application, the term “CTBC code SISO iterative decoding,” is used to refer to the entire method 500 and/or the method 500 minus any front end receiver portions of block 505. The term “IRCC SISO decoding,” depending on the context, can mean performing a single pass of IRCC SISO decoding 515 or multiple passes of IRCC SISO decoding 515. Also, the term “OBC SISO decoding,” depending on the context, can mean performing a single pass through OBC SISO decoding 525 or multiple passes through of OBC SISO decoding 525.

The IRCC SISO decoder 515 can implement a well known soft decoding algorithm such as the BCJR algorithm, or a soft output Viterbi algorithm (SOYA), the min sum algorithm, or any of the MAP, Log-MAP, or the Max-Log-Map algorithms, for example. Such algorithms are known to generate extrinsic information indicative of the reliability of the soft decoded results. For example, if the IRCC SISO decoder 515 involves the BCJR algorithm, then the IRCC SISO decoder 515 will need to compute a sequence of branch transition probabilities, γ's, that each are a function of a respective element of the received signal metrics, rₛ, and a corresponding respective element of updated or initial extrinsic information, the Lₑ's. The IRCC SISO decoder 515 will use this sequence of branch transition probabilities, γ's, while making one forward recursion pass to update a set of state metrics, α's, and one backward recursion pass algorithm to update a set of state metrics, β's. Such concepts are well known in the art in the context of decoding convolutional turbo codes (CTCs). For example, see P. Robertson, et al., “A comparison of optimal and sub-optimal MAP decoding algorithms operating in the log domain,” IEEE ICC 1995, pp. 1009-1013.

The IRCC SISO decoder 515 couples its extrinsic information output to a constrained deinterleaver 520 which deinterleaves the extrinsic information received from the IRCC SISO decoder 515, for example, in accordance with the inverse CI-2 permutation function. The OBC SISO decoder 525 is coupled to receive the deinterleaved extrinsic information from the constrained deinterleaver 520 and, depending on the specific code structure in use, the deinterleaved bit metric (or other type of sample) sequence from the constrained deinterleaver 510. The OBC SISO decoder 525 also preferably implements a known soft decoding algorithm such as the well known Chase-Pyndiah algorithm (also referred to as the Pyndiah algorithm), low complexity Chase-Pyndiah algorithm, the OSD algorithm and its low complexity variations, or any similar soft decoding algorithm for decoding of block codes, for example. In general, different well known (or proprietary) soft decoding algorithms can be used in the blocks 515 and 525. The block 515 will typically use a much simpler decoding algorithm as discussed above to soft decode the IRCC while an algorithm such as, for example, as Are known to those of skill in the art, the Chase-Pyndiah algorithm, the OSD algorithm, or the sum of product algorithm (SPA) will be used in the block 525 to soft decode the outer code, B. In specific embodiments where the outer code is an LDPC code, then the block 525 will carry out one or more iterations of LDPC decoding using the SPA. As a typical number, IRCC SISO decoding 515 of a simple accumulator type IRCC will require about 10% as much decoding (computational) complexity as compared to the OBC SISO decoding 525. The OBC SISO decoder 525 couples its output extrinsic information to a stopping criterion block 530. For example, the block 530 can indicate to stop CTBC code SISO iterations either when a convergence criterion is met, when a fixed number of iterations have been performed, or the lesser thereof. If the stopping criterion block 530 determines that another CTBC code SISO iteration is needed, the OBC SISO decoder 525 also couples its output extrinsic information to a constrained interleaver 535. The constrained interleaver 535 operates according to the same permutation rule designed for the constrained interleaver 410 as discussed above. The output of the constrained interleaver 535 is coupled back to the IRCC SISO decoder 515. If the stopping criterion block 530 determines that another CTBC code SISO iteration is not needed, then iterations are halted and the decoded output message bits are read out of the OBC SISO decoder 525 in natural (deinterleaved) order. The implementation of the soft decoders 515 and 525 and the stopping criterion checker 530 can be implemented using prior art methods. For example, see the above-cited US patents and the well known SISO decoding literature for further details.

The constrained deinterleavers 510, 520 perform the inverse operation of the constrained interleaver 535. If an extrinsic information vector X is permuted to an extrinsic information vector Y by the constrained interleaver 535, then each of the deinterleavers 510, 520 would rearrange the extrinsic information in vector Y to restore the original ordering of the extrinsic information vector X. The constrained interleaver 535 performs its mapping of extrinsic information according to the same permutation rule as used in the constrained interleaver 410 to permute the outer encoded bits.

Another field of prior art relates to using maximum likelihood based measures to determine an improved stopping criterion for computing hard iterative decoding operations. For example, U.S. Pat. No. 8,532,229, “Hard iterative decoding for multilevel codes,” by E. M. Dowling and J. P. Fonseka, is incorporated for reference herein. This patent is incorporated herein by reference to provide the reader with the background information needed to understand certain aspects of the present invention. It is thus to be understood that U.S. Pat. No. 8,532,229 should not be used to interpret any claim language unless specifically related to stopping criterion aspects of the present invention. It would be desirable if certain aspects of the improved maximum likelihood based stopping criteria as discussed in U.S. Pat. No. 8,532,229 could be applied to improve the ability of the CTBC code SISO iterations in the decoder 500 to converge to a correct solution.

Another field of prior art relates to the parallel decoding of serial or parallel concatenated Convolutional Turbo Codes (CTCs). Decoders used to decode CTCs use the same types of decoding algorithms as discussed above in connection with the IRCC SISO decoding 515. SISO decoders for CTCs are used that iterate between two blocks similar to block 515 in a particular configuration similar to the SISO decoder 500, but often with different interconnections between blocks, and different such configurations exist depending on whether the CTC is serial or parallel concatenated, and the specific SISO decoding algorithm in use. In general, the CTC may be viewed as a serial stream of coded bits. This stream may itself appear as a large block containing a window of such CTC encoded bits to be decoded. The prior art has recognized that CTCs can be decoded in parallel by segmenting a block of CTC coded bits into sub-sequences. The sub-sequences are decoded in parallel. For example, one such design is found in J M Hsu, and CL Wang, “A parallel decoding scheme for turbo codes,” IEEE ISCAS′98, pp. 445-448 (“the Hsu reference”). Another well know reference on this subject is R. R. Dobkin et al., “Parallel interleaver design and VLSI architecture for low-latency MAP turbo decoders,” IEEE Transactions on VLSI systems, vol. 13, No. 4, April 2005 (“the Dobkin reference”). A CTC is split up into multiple subsequences that are decoded in parallel. Dummy values are used to initialize the alpha state metric and beta state metric forward and backward recursions as opposed to other known prior art approaches that use a sliding window approach. Although the design and implementation of parallel SISO decoders for CTCs is well known in the art, for the purpose of aiding the reader with lower level details of implementing CTC SISO decoders in parallel, the following US patents are incorporated herein by reference: U.S. Pat. No. 7,783,936, U.S. Pat. No. 8,166,373, and U.S. Pat. No. 7,549,113. When construing the claims of the present patent, it is to be understood that these patents are only incorporated herein to aid in background understanding and should not be used for the purpose of claim interpretation.

Another method to decode a CTC in parallel is provided in S. Yoon, Y. Bar-Ness, “A Parallel MAP Algorithm for Low Latency Turbo Decoding” IEEE Communication Letters, Vol. 6, No. 7, pp. 288-290, July 2002 (“the Soon reference”). In this method, state metric values (alpha and beta values) at a node (between a starting point and a final point of each sub-code block) are indefinite due to simultaneous processing of each sub-decoder. Therefore, an alpha initial value of a first sub-code block (the initial value being the same as set in the ideal Max-Log-MAP algorithm) and a beta initial value of a final sub-code block (the initial value being the same as set in the ideal Max-Log-MAP algorithm) are removed and an alpha initial value and a beta initial value of each sub-code block in initial decoding processing are set to forced or “dummy” values. These initial dummy states can be added so that each parallel subsequence of the CTC gets decoded properly.

Another related field of prior art relates to contention free memory mapping and interleaving for SISO decoders that use parallel processing to decode CTCs. For example, R. Asghar et al., “Memory conflict analysis and implementation of a re-configurable interleaver architecture supporting unified parallel turbo decoding,” J. of Signal Processing systems for signal, image and video technology, 2010, pp. 15-29 (“the Asghar reference”). This method can be used for parallel RCC decoding as well. A key here idea is to determine an interleaving permutation function such that, when implemented on a given parallel VLSI architecture, there will be fewer or no memory contentions (also known as conflicts) when multiple processors attempt to read or write the same one of a set of parallel memory banks at the same memory access cycle. Although the design and implementation of contention free or contention reduced memory mapping and interleaving for parallel SISO decoding of CTCs is known in the art, for the purpose of aiding the reader with some of the lower level details of some specific implementations, the following US patents are incorporated herein by reference: U.S. Pat. No. 8,327,058, and U.S. Pat. No. 7,882,416. When construing the claims of the present patent, it is to be understood that these patents are only incorporated herein to aid in background understanding and should not be used for the purpose of claim interpretation.

Another field of prior art relates to the parallel decoding of Turbo Product Codes (TPCs). For example, Leroux et al, “High-throughput block turbo decoding: from full-parallel architecture to FPGA prototyping,” J. Signal Processing Systems, pp. 349-361, 2009 (“the Leroux reference”), provides a parallel VLSI architecture for decoding a TPC that makes use of a row-column interleaver. Parallel processors are used to process different component inner and outer block codes in parallel. However, this parallel VLSI architecture is specific to a row-column interleaver and both the inner and outer component codes of the TPC are block codes. Other prior art parallel VLSI architectures and chip implementations have been developed for decoding TPCs. However, all such prior art systems need to perform the more costly SISO block decoding twice, once for the inner block code and again for the outer block code in each TPC SISO iteration. Also, all such prior art parallel TPC implementations provide low interleaver gain due to their row-column (or helical or similar) interleaver structure, and can only provide MHD=dₒdᵢ. The SISO decoding used to decode the block component codes of a TPC are the same type as are used by the OBC decoder 525. For further details of the specific computations performed during OBC SISO decoding used in an exemplary OBC SISO decoding algorithm such as the Pyndiah or reduced complexity Pyndiah algorithms, see Xu et al., “A low complexity decoding algorithm for turbo product codes,” IEEE Radio and Wireless Symposium, January, 2007, pp. 209-212.

While parallel processing architectures for TPCs, LDPCs and CTCs have been described in the prior art, and while the families of encoders and decoders described by FIG. 1 and FIG. 2 are known, it would be desirable to have parallel or massively parallel systems that would allow a CTBC code to be decoded using CTBC code SISO iterative decoding 500 in real time under demanding sets of real time processing requirements. For example, in 100 Gbps and beyond optical transport network (OTN) applications, there are 122, 368 message bits per OTN frame and the operating data rates range from 100 Gbps to 400 Gbps (or beyond in future generation systems). It would be desirable to have a massively parallel VLSI system that could perform real-time decoding of CTBC codes, for example, that use large frames such as the OTN frame size, and at high data rates such as on the order of 100 Gbps to 400 Gbps (or more). It would be desirable for the system to be scalable so that other types of specific embodiments could be designed to meet a given set of design specifications, for example, such as are currently specified for turbo product codes (TPCs) in the IEEE Standard 802.11 ad where frame sizes are smaller and the data rates are less demanding. In such cases, it would be desirable to have a scalable architecture that could be embodied with an appropriate number of processors to efficiently meet a given set of design specifications under a set of real-time processing speed requirements. It would be desirable to have a versatile and general massively parallel VLSI system that could be used to design specific apparatus, systems, and methods to support real time decoding of CTBC codes in a wide variety of applications.

### SUMMARY OF THE INVENTION

The present invention provides a family of parallel processing systems for carrying out decoding operations to decode a CTBC encoded signal or similarly encoded signals. Methods, apparatus and systems are provided. The parallel processing systems can be embodied as massively parallel decoder systems using very large scale integration (VLSI) circuits or wafer scale integration (WSI) substrates, for example.

As a optional part of the present invention, a received signal, r(t), is received from a communications channel and demodulated using a front end receiver. The front end receiver is optional because the front end receiver can be implemented separately from the present invention and coupled thereto. That is, certain embodiments of the present invention are receiver and decoder systems that include the front end receiver, while other embodiments are decoder chips and the like that often will not include the front end receiver. The received signal is sampled and converted into digitized sample values. The digitized sample values are eventually converted to bit metrics, or as more broadly defined herein, received signal metrics, of which bit metrics are a special case.

The output from the optional front end receiver are sent to a parallel processing system in accordance with an aspect of the present invention. For example, an input signal distribution unit can be coupled to receive digitized information related to the input signal, r(t), and to distribute a plurality of respective subsequences of digitized received signal input information elements to a plurality of respective local memory banks associated with a respective processor in the parallel processing system. The local memory banks can be implemented as multiport memory banks to receive these digitized received signal input information subsequences, or each respective processor can read and possibly perform additional processing of the distributed information before moving it into a local memory that is, for example, not multiported. For example, the respective subsequences of digitized received signal input information elements can be signal samples, bit metrics, or, any form of received signal metrics related to distances between samples of the received signal, r(t), and known constellation points related to a transmit signal constellation.

Whatever form these digitized received signal input information elements take, another aspect of the present invention involves a parallel architecture and a parallel processing method that distributes M respective subsequences of these digitized received signal input information elements to M respective memory banks, where M is an integer and M≧1. This can be achieved, for example, by including a connection and optionally an input processor for coupling the digitized received signal input information elements to an input port of an interconnection network that causes the elements of the input signal or metrics related to the input signal to be distributed to the M respective memory banks. Each of the M respective memory banks is coupled to a respective one of a set of M processors. The M processors are configured to be able to process information in parallel on M different respective sets of data. Each of the M respective memory banks may be a local memory bank that is directly accessible only to its. respective one of the M processors, or each of the M respective memory banks could be implemented as a multiported memory bank that is shared with one or more other portions of the parallel processing system. Also, for example, if the M respective subsequences of digitized received signal input information elements that are distributed to the M respective processors are samples of the received signal, r(t), then each of the M processors could convert these signal samples to a respective set of bit metrics or other types of received signal metrics, for example. Alternatively, depending on the embodiment, the M respective subsequences of digitized received signal input information elements that are distributed to the M respective processors could comprise the bit metrics or more generally, the received signal metrics, themselves.

An aspect of the present invention contemplates that the received signal, r(t), has been transmitted from a transmitter that converted a sequence of message bits into a CTBC encoded transmit signal, and transmitted the CTBC encoded signal through a channel before being received. The channel is assumed to have added noise and possibly other distortions to the received signal, r(t), so that decoding operations are needed to reduce an error measure associated with recovered message bits that correspond to the CTBC encoded message bits encoded into in the transmit signal. Hence, in accordance with an aspect of the present invention, parallel (or massively parallel) CTBC code SISO iterative decoding is performed to recover the message sequence encoded into the transmit signal with a bit error rate that is low enough to meet a given communication system design specification.

Hence, in accordance with the present invention, each respective one of the M processors performs (in parallel with the other processors) a respective pass of IRCC SISO decoding to produce a respective subsequence of IRCC SISO decoding output information elements. In many embodiments the IRCC SISO decoding output information elements are equal to IRCC SISO decoding updated extrinsic information elements. In other examples, mathematical manipulations may be performed to the IRCC SISO decoding updated extrinsic information elements to derive the IRCC SISO decoding output information elements, or, depending on the IRCC decoding algorithm in use, other types of IRCC SISO decoding output information elements may be generated and transferred for subsequent OBC SISO decoding.

In typical embodiments, each a respective subsequence of extrinsic information elements is initially set to zero and the received signal metrics are used together with a version of a parallel CTC SISO decoding algorithm as described above. The parallel CTC SISO decoding algorithm may further be adapted to specifically perform parallel IRCC SISO decoding in accordance with an aspect of the present invention to thereby update the respective subsequence of extrinsic information elements in accordance with the IRCC SISO decoding 515.

Normally, as the above parallel IRCC SISO decoding is performed, each respective one of the M processors couples its respective subsequence of IRCC SISO decoding output elements to a respective input port configured to receive inputs for parallel constrained deinterleaving. For example, the input port can be coupled to a parallel constrained deinterleaver. The parallel constrained deinterleaver may be implemented, for example, as an interconnection network coupled to addressing and sequencing control logic. The job of the parallel constrained deinterleaver is typically to apply a CI-2 inverse permutation function to the set of M respective subsequences of IRCC SISO decoding output information elements and to redistribute these IRCC SISO decoding output information elements to respective target locations within the parallel system using a plurality of switchable data paths and optional address sequencing and buffering. Preferably, the processors performing IRCC SISO decoding send a stream of outputs to the parallel constrained deinterleaver, possibly via a multiported register bank. As the stream of outputs is received at a port of the parallel deinterleaver, the processor preferably begins working on computing the next output in the stream of IRCC SISO decoding outputs.

An aspect of the present invention also involves performing parallel constrained deinterleaving in order to distribute, in parallel, plural selected ones of IRCC SISO decoding output information elements to a set of respective target memory locations located in respective target ones of a set of N≧M multiport memory banks (for example the I-REG register banks, or the O-REG register banks, or their equivalents or variants as discussed hereinbelow). Each respective one of the N multiport memory banks preferably has at least a first port configured to receive the IRCC SISO decoding output information elements from the constrained deinterleaving, and a second port coupled to a respective one of a set of N parallel processors. Typically the parallel constrained deinterleaving is performed by the parallel constrained interleaver mentioned above. The constrained deinterleaver can optionally be used to redistribute the received signal metrics to N processors so that, in terms of the outer code B, each of the N processors will have received K≧1 codewords worth of IRCC SISO decoding output information elements (e.g., updated extrinsic information elements) and optionally the corresponding received signal metrics related thereto.

In accordance with another aspect of the present invention, each respective one of the N parallel processors, performs, in parallel, a pass of OBC SISO decoding to produce a respective subsequence of OBC SISO decoding output information elements associated with one or more codewords of the outer block code, B. Each OBC SISO decoding output information element is associated with a respective OBC SISO decoding updated extrinsic information element. For example, certain embodiments the OBC SISO decoding output information element may be equal to a corresponding OBC SISO decoding updated extrinsic information element. In other embodiments, a corresponding respective received signal metric can be added to the OBC SISO decoding updated extrinsic information element to form a gamma value that will be used in subsequent IRCC SISO decoding. Other types of outputs could also alternatively be extracted from the OBC SISO decoding in different embodiments, depending on the details of the OBC SISO decoding and/or IRCC SISO decoding algorithms in use.

The present invention runs CTBC code SISO iterations until a stopping criterion is met. The stopping criterion may be as simple as allowing a fixed number of CTBC code SISO iterations to complete. In such cases, no explicit stopping criterion checking is needed, because the program sequencing in the parallel system will implicitly know when the fixed number of CTBC code SISO iterations have completed. Alternatively, a convergence criterion can be checked and iterations can be stopped early if the convergence criterion is met before the fixed number of CTBC code SISO iterations have completed. In the event that the stopping criterion has not been met, the system

In the event that the stopping criterion has not been met, parallel constrained interleaving of the N respective subsequences of OBC SISO decoding output information elements is performed. This operation is typically performed by a parallel constrained interleaver. The parallel constrained interleaver may be implemented, similarly to the parallel constrained deinterleaver discussed above, as an interconnection network coupled to addressing and sequencing control logic. The job of the parallel constrained interleaver is typically to apply a CI-2 permutation function to the set of N respective subsequences of OBC SISO decoding output information elements and to redistribute these information elements to target locations within the parallel system using a plurality of switchable data paths and optional address sequencing and buffering. In general, the parallel constrained interleaving involves distributing selected ones of the OBC SISO decoding output information elements to a set of M multiport memory locations associated with the set of M parallel processors. The above actions minus the portions related to receiving, processing and deinterleaving the received signal metrics are repeated until the stopping criterion is met.

Once the stopping criterion has been met a set of decoded message bits are preferably output from the N processors. For example, the N processors can make hard decisions and output this information via one or more an interconnection network paths that couple each of the N processors to a common decoded message bit output port.

In the above discussion, the M processors perform their respective passes of IRCC SISO decoding substantially in parallel with each other, and the N processors perform their respective passes of OBC SISO decoding substantially in parallel with each other. Depending on the embodiment, the M processors can be different from the N processors, or M processors could be a subset of the N processors. In many embodiments of the present invention, M=N, and in such cases, the M processors could identically the same as the N processors. Depending on the embodiment, the M multiport memory banks can thus also be multiport memory banks that are different from the N multiport memory banks. Alternatively, the M multiport memory banks could be a subset of the N multiport memory banks. In embodiments where M=N, the M multiport memory banks could thus be identically the same as the N multiport memory banks.

### BRIEF DESCRIPTION OF THE FIGURES

The various novel features of the present invention are illustrated in the figures listed below and described in the detailed description that follows.

FIG. 1 is a block diagram of an embodiment of a prior art encoder that encodes data bits in accordance a constrained turbo block convolutional (CTBC) code and maps the CTBC encoded sequence to a channel for transmission.

FIG. 2 is a block diagram of an embodiment of a prior art receiver method and apparatus that makes use of an iterative soft input soft output (SISO) decoder to decode a received version of a CTBC code such as generated by FIG. 1.

FIG. 3 is a block diagram of an embodiment of a massively parallel VLSI system suitable for executing the SISO decoder of FIG. 2, or variations thereof, under demanding real-time speed requirements.

FIG. 4 is a block diagram illustrating forward and reverse direction interconnection network data paths used to carry out the CI-2 interleaving and deinterleaving operations in the massively parallel system of FIG. 3.

FIG. 5 is a block diagram illustrating an exemplary embodiment of an interconnection network and address sequencing logic (INASL) block compatible for use with FIG. 3 using the data path logic described in connection with FIG. 4.

FIG. 6 is a diagram showing matrix representations of information involved for use in computer aided design of parallel SISO decoders for decoding CTBC codes.

FIG. 7 is a flow chart showing an exemplary embodiment of a computer aided design process used to optimize the performance or parallel transfer cycles involved in the parallel constrained interleaving and deinterleaving portions of CTBC code SISO decoding.

FIG. 8 is a block diagram illustrating an alternative embodiment of the system 600 that uses additional processors for performing recursive convolutional decoding to increase throughput and reduce latency as compared to the system of FIG. 3.

FIG. 9 is a flow chart showing an exemplary embodiment of a processing loop performed by various parallel CTBC CODE SISO iterative decoding systems of the present invention.

FIG. 10 is a block diagram illustrating an alternative embodiment of the system 600 that fewer multiported memory resources and thus saves VLSI area resources related to the multiport memory portions of the parallel CTBC CODE SISO iterative decoders.

FIG. 11 is a flow chart showing an exemplary embodiment of a processing loop performed by various parallel CTBC CODE SISO iterative decoding systems of the present invention.

### DETAILED DESCRIPTION OF THE PREFERRED EMBODIMENTS

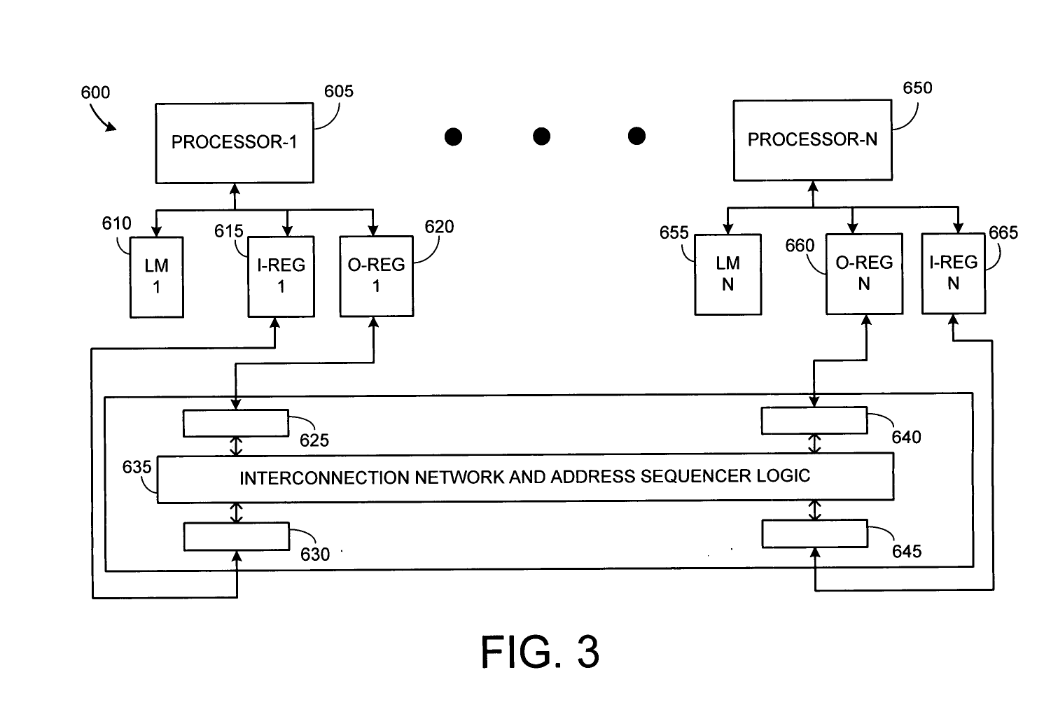

FIG. 3 shows, in accordance with the present invention, a massively parallel very large scale integration (VLSI) system 600 for decoding CTBC codes or variations thereof. Depending on the number of processors employed, the system 600 can be implemented on a single VLSI substrate, on a circuit carrier such as a circuit board or hybrid chip module that interconnects multiple VLSI substrates into a larger VLSI system, or on a wafer (or sub-wafer) level substrate as used in wafer scale integration (WSI). Depending on the embodiment, the system of FIG. 3 can be viewed as one or more VLSI chips, a WSI system, a parallel processing system, a device, or an apparatus. Thus it is to be understood that any reference to the system 600 can refer to any particular type of such embodiments. The system 600 and the general design philosophy that guides the design of the system 600 is explained in connection with FIG. 3 through FIG. 7.

To understand the operation of the system 600, consider a CTBC code that uses an outer code B that corresponds to a finite length code, for example, an (n,k) block code and an inner recursive convolutional code (IRCC). For example, the outer code B can be selected to be a (72, 64) shortened BCH code and the IRCC, could be selected, for example, to be a rate-1 accumulator given by G(D)=1/(1+D), or the rate-1 accumulator followed by a (λ,λ−1) SPC as discussed above. In optical transport network (OTN) applications, because each OTN frame is specified to include 122, 368 message bits, it is convenient to choose ρ=239 and L=8 since 122, 368÷239÷8=64. With these exemplary parameters, the length of the constrained interleaver used by this CTBC code is given by M_{CTBC}=Lρn=8×239×72=137, 644. The number 137, 644 corresponds to the number of coded bits per OTN frame for this choice of CTBC code, while 122, 368 corresponds to the number of message bits per OTN frame. In this example, a CI-2 interleaver is designed using an L×ρn=L×(239*72)=8×1912 constrained interleaver design matrix whose elements can be considered to be equal to bits encoded in accordance with the outer code B. It should also be mentioned that CTBC codes can be used in many other applications beside OTN applications, for example such as wireless data applications, and the numbers ρ, L, and n can be significantly different in these applications, but the above numbers will be used herein by way of example only. Any suitable set of numbers for ρ, L, and n can be used without departing from the scope of the present invention.

While in a preferred embodiment of the present invention the OBC is selected to be an (n,k) block code B, the OBC can alternatively be a finite length convolutional code, a finite-length sub-sequence of a recursive convolutional code, a fixed-length tail biting convolutional code, or could be a low density parity check code (LDPC), each of which can be considered to be a particular selection of a suitable and allowable block code B. In the type of alternative embodiment where the OBC SISO decoder 525 is an LDPC decoder, then in some embodiments it may be desirable to only run one LDPC iteration between variable and check nodes instead of multiple LDPC iterations per pass through the overall iterative decoder 500.

Once the CI-2 design process as discussed above and in the above cited US patents and the Fonseka [1] reference are applied to determine a specific constrained interleaver design matrix for the specific CTBC code being designed, a CI-2 permutation function and inverse permutation function pair will be available. It is noted that the present invention can also be used with different constraints than the CI-2 constraints. For example, additional constraints can be also be applied in accordance with a set of CI-3 design rules as discussed in U.S. Pat. No. 8,532,209 without departing from the scope of the present invention. In accordance with an aspect of the present invention, other types of constraints that eliminate inefficient usage of hardware resources can also optionally be applied in the constrained interleaver design process. A general aspect of the present invention is to design transformations and to apply these transformations to transform a first valid CI-2 design matrix to a second valid CI-2 design matrix. The transform is preferably selected to reduce one or more target performance measures that are associated with a corresponding set of parallel transfer cycles in order to implement in parallel the CI-2 permutation function and inverse permutation function pair associated with second (transformed) CI-2 design matrix. Various examples of such transformations are discussed hereinbelow.

Embodiments of the system 600 can be designed where there are N=ρL/K processors available, so that each processor decodes K codewords of the outer code B during OBC SISO decoding 525, and each processor decodes an nK—element subsequence of the IRCC while performing IRCC SISO decoding 515. Here K is a positive integer and preferably, 1≦K≦L. Note that when K=1, N=ρL, and corresponds to an embodiment of the system 600 that exploits the maximum amount of parallelism at the codeword level. Note also that when K=L, N=ρ, and this corresponds to a system that exploits a lower level of parallelism. If K>L, then even less parallelism is exploited at the codeword level, however, such embodiments are possible. When such K≧L embodiments are used, the processors 605, . . . , 650 are preferably designed to be more powerful so as to exploit higher amounts of lower level parallelism exploitable within one or more SISO decoding iterations and/or at the instruction level of parallelism. As discussed in the context of a class of alternative embodiments below, the processors 605, . . . 650 can be implemented as dual core processors that are kept busy during CTBC code SISO iterative decoding. Such embodiments can reduce the number of data paths needed INASL 635.

In the context of the above specific exemplary OTN-type embodiment, again consider the system 600. The system 600 includes a set of N processors, Processor-1 605 to Processor-N 650, where N is a positive integer, and typically N≦ρL, e.g., N=ρ, or N=ρL/4, N=ρL/2, or N=ρL could be used, depending on VLSI area availability and speed requirements, etc. As is discussed below, the processors 605, . . . 650 can be controlled by one or more instructions streams or threads. For example, the processors 605, . . . 650 can be responsive to a single instruction stream, and in response thereto, carry out the same actions on multiple data sets which correspond to decoding operations on different codewords of the outer code B or different subsequences of the inner recursive convolutional code (IRCC). The parallel processing system 600 designed so that the processors 605, . . . , 650 all synchronously execute the same instruction stream but apply each instruction to different data sets is called a “single instruction multiple data” (SIMD) embodiment. Pipelining registers can be used to reduce propagation delays caused by sending a single instruction stream to multiple processors, for example, on a VLSI chip, a WSI substrate or a multiple chip circuit embodiment. Each of the processors 605, . . . , 650 can be embodied to include local flags (also known as condition codes or condition code registers) and other similar processor-local variables, so that different ones of the processors executing the same instruction can take different actions based on local data and/or condition codes. As discussed below, SIMD embodiments of the present invention can optionally include local state-machine pattern generators at each processor to provide further flexibility. The local state machine pattern generator can generate local address sequences and the like at each processor to design various efficient SIMD parallel CTBC decoder embodiments.

Alternatively, the parallel processing system 600 can be designed so that the processors 605, . . . , 650 simultaneously execute individual instruction streams (also known as program threads). When the different processors 605, . . . , 650 execute multiple instruction streams (threads) at the same time and operate on multiple different data sets (e.g., different codewords of the outer code B or sub-sequences of the IRCC) at the same time, such multithreaded embodiments are referred to as “multiple instruction multiple data” (MIMD) embodiments. Typically a SIMD embodiment requires fewer instruction memory resources and is more efficient in terms of silicon area and power consumption. In this patent application, various embodiments of the present invention are provided. Any of the embodiments described herein or their equivalents or variations thereof can be designed using SIMD, MIMD, or a mixed SIMD/MIMD approach.

In general, as used defined herein, the phrase “sequence of control inputs” is used to refer to any one or combination of 1) a SIMD instruction stream sent to a plurality of processors, 2) a plurality of MIMD instruction streams being simultaneously sent to a plurality of processors, 3) a sequence of control signals or output state signals generated by a state machine such as a pattern generator state machine, 4) a sequence of very long instruction word (VLIWs) used to control one or more architectural elements in a manner similar to microcode controlled systems, where the VLIWs can be read out of a VLIW memory, or generated by a state machine, or a combination of both. Such sequences of control inputs are either encoded into a memory, or are hard wired into state machine logic on a given parallel processing system embodiment. Therefore, it is to be understood that such sequences of control inputs correspond to elements of an apparatus or system, much like a memory into which a program is written is considered to be an element of an apparatus of system. The “sequences of control inputs” type language is broad enough to encompass a computer program or a hardware description language type program that defines a state machine or other element that generates a corresponding sequence of control inputs that cause a particular element of the system or apparatus to behave in a particular way.

Each processor preferably includes a local memory (LM) 610, . . . , 655, a multi-ported inner code register bank (“I-REG register bank”) 615, . . . , 665 (or more generally, a multi-ported memory bank), and a multi-ported outer code register bank (memory area) (“O-REG register bank”) 620, . . . , 660 (or more generally, a multi-ported memory bank). In FIG. 3, the double arrows connecting blocks 605,610,615, and 620, and the double arrows connecting blocks 650,655,660, and 665 represent bi-directional data busses or other types of bi-directional data paths. The number of bus lines in these busses is a design parameter. The reason multi-ported register banks are provided is to allow the processors 605, . . . 650 to access a given respective multi-ported register bank using a first port and to also allow an interconnection network and address sequencer logic (INASL) block 635 to access the given respective multi-ported register bank using a second port. In accordance with the parallel processing arts, the given respective multi-ported register bank may be viewed as a shared memory, to be shared by a given one of the processors for decoding operations 515, 525 and by the INASL 635 which may be viewed as a system-level parallel data-movement processor (or subsystem) that implements a set of parallel data transfer cycles in order to implement the interleaving/deinterleaving operations 510,520,535, in accordance with the pre-determined CI-2 permutation function and inverse permutation function pair.

While performing parallel CTBC code SISO iterative decoding in accordance with the present invention, the I-REG register banks 615, . . . , 665 are usually used as IRCC subsequence input buffers for a subsequent pass of IRCC SISO decoding. Also, the O-REG register banks 620, . . . , 660 are usually used as updated codeword extrinsic information input buffers for a subsequent pass of OBC SISO decoding. When the processors 605, . . . , 650 are performing a pass of IRCC SISO decoding, a stream of outputs will be generated that will need to be passed to the INASL 635 to be transferred to a target location in a target one of the O-REG register banks. When the processors 605, . . . , 650 are performing a pass of OBC SISO decoding, a stream of outputs will be to generated that will need to be passed to the INASL 635 to be transferred to a target location in a target one of the I-REG register banks. To perform this streaming, a special output port can be used, or an additional location in the I-REG and O-REG register files can be dedicated for outputting the stream of outputs to the INASL 635. Such operation is similar in the systems 800 and 1000 and their alternative embodiments and variants.

As a practical matter, only so many processors will fit on a given substrate such as a VLSI chip. The closer that processors can be kept busy executing CTBC code SISO iterations 100% of the time, then closer the system 600 is to being perfectly efficient from the processor level of granularity. Hence the system 600 is designed so that the processors 605, . . . 650 are programmed to continuously alternate between IRCC SISO decoding 515 and OBC SISO decoding, 525. It is the job of the INASL 635 to perform the deinterleaving 510, 512 operations and the interleaving operations 535 to keep the processor 605, . . . 650 from having to wait for new data to arrive. As discussed in FIG. 3 to FIG. 7, various the INASL 635 can be designed to completely eliminate or to significantly reduce any such waiting times, to thereby keep the processors 605, . . . , 650 busy 100% or nearly 100% of the time.

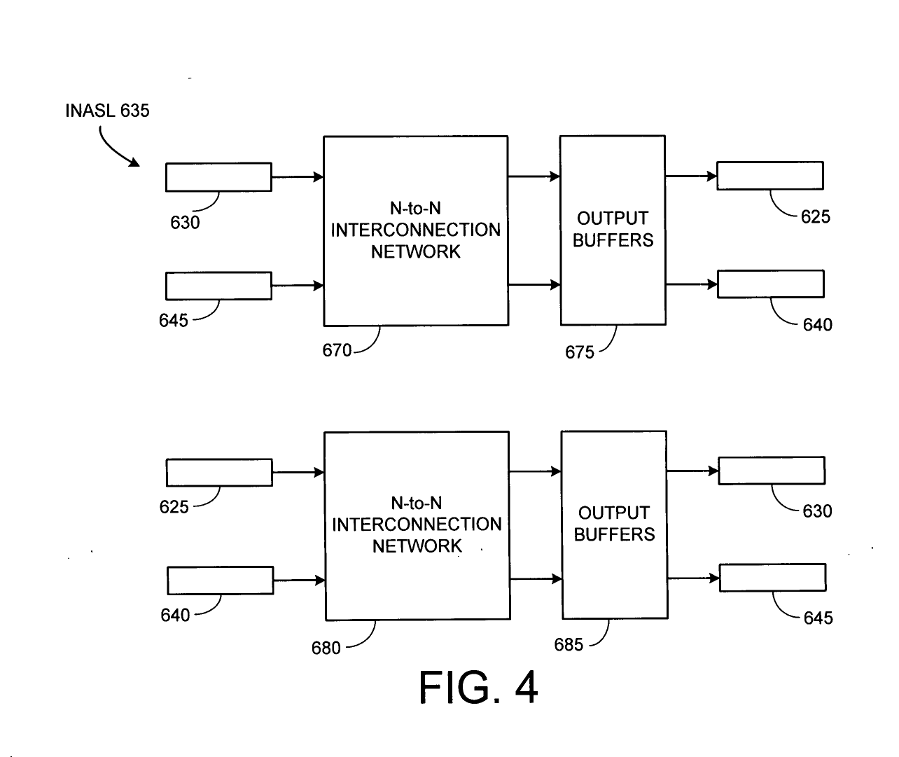

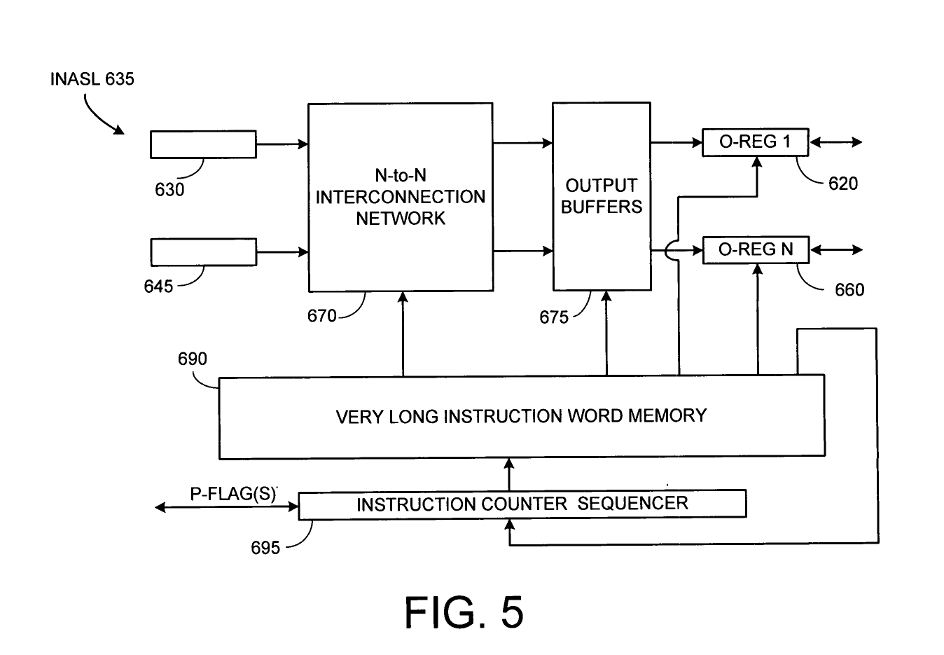

It is to be understood that the INASL 635 is an exemplary embodiment of a device that can perform parallel constrained interleaving and parallel constrained deinterleaving. In the course of CTBC code SISO iterative decoding, constrained deinterleaving is performed at blocks 510 and 520 in FIG. 5. A “parallel constrained deinterleaver” generally refers to any device or sub-system that performs the operations of the constrained deinterleaving blocks 510 and/or 520 in parallel in order to provide deinterleaved subsequences comprising one or more codewords of the outer code B to N different processors in a parallel processing system such as the system 600 (or 800 or 1000 or equivalents of variations thereof) where multiple processors are deployed to perform OCB SISO decoding and/or IRCC decoding. A “parallel constrained interleaver” generally refers to any device or sub-system that performs the operations of the constrained interleaving block 535 in parallel in order to provide one or more interleaved subsequences of the IRCC to one or more processors in a parallel processing system such as the system 600 (or 800 or 1000 or equivalents of variations thereof) where multiple processors are deployed to perform OCB SISO decoding and/or IRCC decoding. The verb “parallel constrained deinterleaving” referrers to the operations performed by a parallel deinterleaver and the verb “parallel constrained interleaving” referrers to the operations performed by a parallel interleaver. In this context, the INASL 635 can be understood to represent a family of embodiments devices that perform parallel constrained deinterleaving and parallel constrained interleaving. FIG. 4 shows an exemplary embodiment of how the forward and backward paths through the INASL 635 perform these functions.

As explained in the P. Robertson et al. reference as cited above, as a first step of IRCC SISO decoding, a corresponding element of the input metric vector, rₛ, will be added to each updated element of extrinsic information in order to compute a set of gamma values. Hence in all embodiments discussed herein, it is recognized that the gamma values can be sent through the INASL 635 instead of updated OBC SISO decoding extrinsic information. The processors 605, . . . , 650 can perform this addition before sending the updated extrinsic information through the INASL to its destination I-REG register bank.

The processors can be designed in a variety of ways, but in general, each processor is preferably implemented as a processor whose instruction set includes special instructions and/or lookup tables that are optimized to perform the specific computational operations used in OBC SISO decoding and/or IRCC SISO decoding. Preferably, the processors are application specific and have reduced instruction sets that eliminate instructions that are not specifically needed for CTBC code SISO iterative decoding. That is, preferred embodiments use specially designed processors designed to perform OBC SISO decoding and/or IRCC SISO decoding operations and are designed to be as simple and streamlined as possible. The processors 605, . . . , 650 can also optionally be architected to exploit lower level parallelism available in the individual passes through OBC SISO decoding and/or IRCC SISO decoding. Multiple functional units can be implemented in each of these processors to take advantage of lower level parallelism at either or both of the SISO decoding level and/or the instruction level. In this patent application, the term “functional unit” refers to a sub-portion of a processor, for example an arithmetic logic unit, an addressing unit, a data movement unit, a lookup table implemented calculation unit, and the like. The functional unit can be designed to be responsive to an instruction or sub-instruction that is executed by the processor. Alternatively, because of the repetitive nature of the CTBC code SISO iterative decoding, one or more functional units can be included in each processor to execute a state machine, for example, a pattern generator state machine used to generate a set of outputs such as addresses or sub-addresses in accordance with a predetermined sequencing. For example, each processor can generate a respective sequence of bit patterns such as addresses or least significant bits of address sequences, or the like, in synchronization with the instructions executed by the respective processor. In such embodiments, this type of state machine functional unit need not respond to the instruction stream executed by the respective processor. Pipelining may be preferably employed as a means of exploiting aspects of instruction level parallelism.

An aspect of the present invention contemplates applying higher level parallelism by performing OBC SISO decoding to decode multiple to different codewords of the outer code B in parallel, and by also performing IRCC SISO decoding to decode multiple different subsequences of the IRCC in parallel. The present invention also contemplates applying instruction level and/or other types of lower level parallelism within the processors themselves to exploit parallelism within each of the processors as they execute each pass through OBC SISO decoding and/or IRCC SISO decoding. For example, each of the processors 605, . . . 650 could be implemented as a dual core processor. At different times, both cores could be performing OBC SISO decoding on different codewords. At other times, both cores could be performing different computations such as the different subsequences of gamma value updating and forward and backward state metric recursions of the log-MAP algorithm, and both cores could then compute different subsequences of extrinsic information. At other times, as discussed below, one core could be still working in the IRCC SISO decoding operations while the other is performing OBC SISO decoding on a codeword of the outer code B that has already propagated through the INASL 650.

In some alternative embodiments the local memories 610, . . . , 665 can be implemented as multiported memories (second port connections not shown in FIGS. 3, 8 and 10). For example, the LMs 610, . . . , 665 can be optionally include an additional port for coupling to the INASL 635 and/or an additional port(s) for coupling to one or more (e.g., two) neighboring processors or for coupling to a port of the LMs associated with the one or more neighboring processors. In some algorithms (e.g., sliding window/overlapped approach of Hsu as referenced above) for IRCC SISO decoding, the segmentation of the IRCC into a set of N subsequences to be decoded in parallel requires some communication with neighboring processors. However, the INASL 635 can be alternatively be used to implement any type of interprocessor communication, to include passing overlapping IRCC SISO decoding related information between neighboring processors. In many embodiments, the INASL 635 is coupled to a set of multiport memory locations collocated with each of the parallel processors, and thus the INASL 635 can be used for interprocessor communications, to distribute digitized input signal information elements such as received signal metrics to the processors, and to collect decoded message bits from the processors. The local memories 610, . . . , 665, and the processors 605, . . . , 650 can thus receive input information, send output information, and exchange inter-processor communications information via the INASL 635 and the multiported memory banks (e.g., I-REG register banks and the O-REG register banks).

In this patent application, the term “register” and the term “memory” can mean the same thing. There are generally two main types of memory, dynamic random access memory (DRAM) and static random access memory (SRAM). Registers are typically implemented using SRAM. The term “memory” is often used to refer to banks of random access memory for use in storing data and/or instructions. The term “register” is often used to describe a SRAM embodiment that is used in a specific circuit for a specific purpose. Examples include register banks that are tightly coupled to one or more arithmetic logic units (ALUs) in a processor. Registers are also used in circuits like hardware implemented shift registers, hardware implemented first-in-first-out buffers, pipelined data paths, pipelined instruction paths, and the like. In this patent application, the term “multi-ported register” refers to a register that can be read and/or written by more than one different modules (such as arithmetic processors and/or data movement subsystems). A multiport register is typically implemented as a regular register, but with additional multiplexing/demultiplexing switching logic deployed in the input/output data paths of the regular register to allow the different modules to read and/or write the multi-ported register. More generally, a multi-ported register can be viewed as one or more locations of shared memory as are known in the art. In the present invention, the multiport registers are often dual ported, but in general, the term multiport is used to indicate that two or more ports may be used, depending on the needs of a given specific embodiment. For example, a given processor can have multiple functional units and a given register may be implemented as two separate registers, one for a forward direction and another for a reverse direction of data flow. At a lower level of abstraction, what appears as a dual port register at the architectural level may appear as a multi-ported register with more than two ports when implemented in hardware.

The I-REG register bank 615 is coupled to one or more optional registers 630 that are coupled to an interconnection network and address sequencer logic (INASL) block 635. The one or more registers 630 provide a registered data path to allow information to be read from and/or written to the I-REG register bank 615. The O-REG register bank 620 is coupled to one or more optional registers 625 that are also coupled to the INASL block 635. The one or more optional registers 625 provide a registered data path to allow information to be read from and written to the multi-ported outer code register bank 620. Similarly, the I-REG register bank 665 is coupled to one or more optional registers 645 that are coupled to the INASL 635. The one or more optional registers 645 provide a registered data path to allow information to be read from and written to the I-REG register bank 665. The multi-ported outer code register bank 660 is coupled to one or more optional registers 640 that are also coupled to the INASL block 635. The one or more registers 640 provide a registered data path to allow information to be read from and written to the multi-ported outer code register bank 660. Depending on the embodiment, the register(s) 630 may be implemented in the same multi-ported memory bank as the inner code registers 615, the register(s) 625 may be implemented in the same multi-ported memory bank as the outer code registers 620, the register(s) 645 may be implemented in the same multi-ported memory bank as the inner code registers 665, the register(s) 640 may be implemented in the same multi-ported memory bank as the outer code registers 660. That is, the I/O registers 625, . . . , 640, and 630, . . . , 645 can optionally be integrated into the register banks 615, . . . , 665, and 620, . . . 660. Similarly, any or all of the I/O registers 625, 630, . . . 640, 645 can be integrated into the a buffered switching fabric in embodiments of the INASL 635 that make use of a buffered switching fabric.

A buffered switching fabric as defined herein generally refers to any interconnection network that deploys registers in one or more of its data paths. The registers can include input registers, output registers, registers between stages of a multistage interconnection network, leaf nodes of a mesh of trees interconnection network, or as nodes of other interconnection other interconnection network topologies, for example.

As also defined herein, the phrase “parallel transfer cycle” refers to an operation whereby N inputs to the INASL 635 are passed to M≦N output channels. Similarly, the term parallel transfer cycle can refer to the passage of multiple data elements in parallel through a parallel interleaver and/or a parallel deinterleaver. In some cases a parallel transfer cycle will simply pass N data elements received on N input lines to N output lines in a permuted order. As discussed below, to implement the CI-2 and the CI-2 inverse permutation functions on the parallel system 600, at times the N data elements presented on the N input lines to the INASL 635 will each need to be directed to a respective target memory location in a respective specific target register bank location that resides in one of M<N different ones of the I-REG banks 615, . . . , 665, or the O-REG banks 620, . . . , 660. In such cases, depending on the design implementation of the switching fabric within the INASL 635, a parallel transfer cycle may require multiple data path configuration cycles and multiple passes of different subsets of data elements through the INASL 635. For example, multiple passes through an N:N crossbar switch or a specific multistage interconnection network (e.g., 670 or 680 in FIG. 4 and/or FIG. 5) can be made using, e.g., three passes, N-to-M1, N-to-M2 and N-to-M3 respective subsets of M1, M2 and M3 output ports. In this example, all three of these passes, taken together, provide one complete parallel transfer cycle through the INASL 635. By the time the parallel data transfer cycle is complete, all N input data elements will have been transferred to M<N output ports, and certain ones of the M<N output ports will have more than one data element sent to those certain ones of the output ports. Internal buffering in the INASL and/or hidden nodes can optionally be deployed into a buffered switching fabric within the INASL 635 to reduce the clock cycles needed to perform the various N-to-M parallel transfer cycles that may be needed to implement the CI-2 permutation and inverse permutation function pair. Certain preferred embodiments of the present invention use output FIFO queues at each output port of the INASL 635 to deal with the cases where multiple inputs are mapped to a particular output port of the INASL 635 during a parallel transfer cycle. In such embodiments, sequencing logic in the INASL 635 is used to generate the needed addressing sequences for the target register banks and to control the clocking of the contents of the FIFO queues into a set of respective the target locations in the respective target multi-ported register banks involved in the parallel transfer cycle.

The INASL 635 is preferably implemented be responsive to control inputs that configure the INASL 635 to implement a corresponding set of N-port to M-port interconnection data paths, where M≦N. Whenever M<N, one or more of the output ports, e.g., 625, . . . , 640 will need to receive more than one metric or updated element of extrinsic information. Similarly, after the OBC SISO decoding, the input ports of the INASL 635 become registers 625-640 and the output ports become registers 630-645. After OBC SISO decoding, the same types of N-port to M-port interconnection patterns where multiple data elements map to selected output ports may be needed. The INASL 635 is preferably implemented in such a way as to support the routing/switching of N parallel elements of updated extrinsic information to M<=N of the buffered output ports, e.g., 630, . . . , 645. Preferred embodiments of the INASL 635 and/or the dynamically switchable data paths needed implement this functionality are described in connection with FIG. 4 and FIG. 5 below.

In the context of interconnection networks, “contention” generally refers to events whereby a given permutation or sub-permutation cannot be performed in a single clock cycle because two inputs need to access a same internal resource such as a register or particular path in an internal switching node in order to eventually reach their respective destination ports. Some interconnection networks like a cross bar switch are contentionless since all the internal data paths are supplied to avoid such contentions. In this patent application, the phrase “output contention” arises in the special cases where the INASL 635 needs to complete a parallel transfer cycle where the N inputs will be mapped to M<N output ports, and certain ones of the M output ports will have more than one of the inputs mapped thereto. That is, instead of contention at an internal node, an output contention event occurs when one or more subsets containing multiple ones of the N inputs to the INASL 635 map to M<N respective output ports. Such output contentions can cause the parallel transfer cycle to require multiple passes through the switching fabric of the INASL 635, or can alternatively require the switching fabric of the INASL to consume more area and power due to the addition of data paths, hidden nodes, and/or additional buffering and output sequencing logic and/or operation cycles.

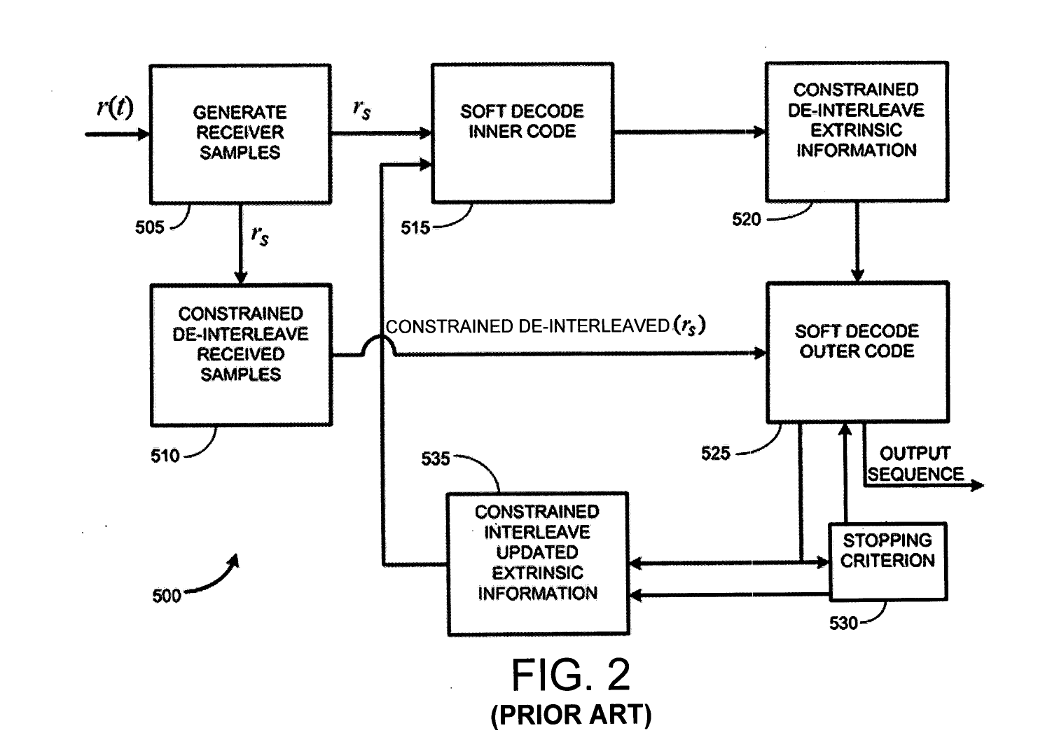

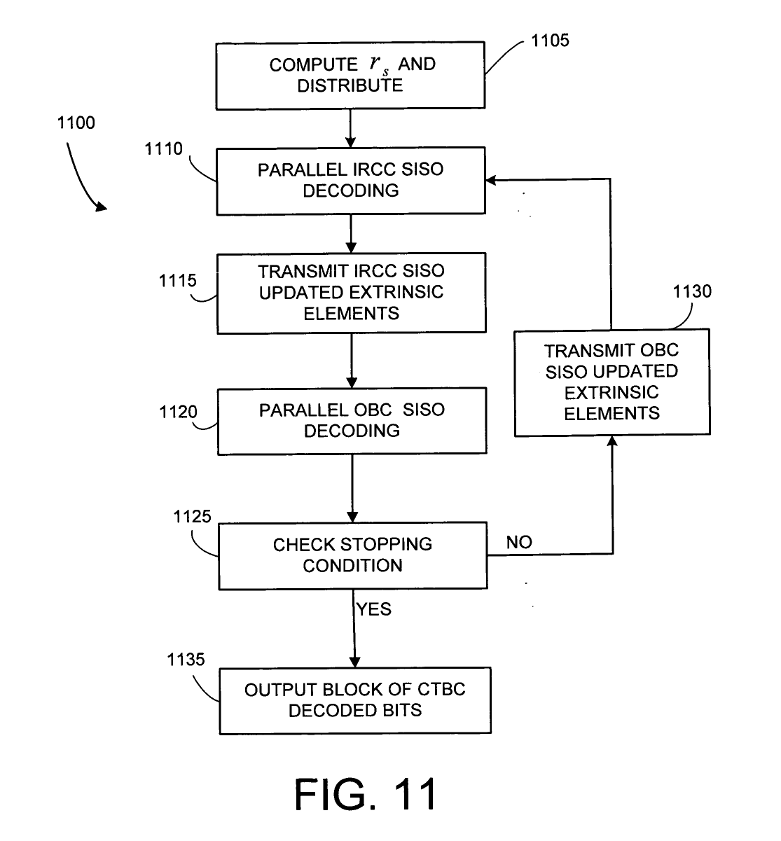

In operation, the system 600 is used in decoding a pre-specified CTBC code. This is also discussed in more general terms in connection with FIG. 11 below. For example, decoding as per FIG. 2 is carried out with the vector rₛ being divided into N consecutive sub-vectors, each, to be sent to a respective sequential one of the N I-REG register banks 615, . . . , 665. Next each of the processors 605, . . . , 650 execute in parallel a pass of IRCC SISO decoding on the sub-sequence of extrinsic information stored in the respective I-REG register bank, for example using a parallelized BJCR, log-MAP, SOVA algorithm or similar RCC SISO decoding algorithms as discussed above. This decoding pass is performed at each respective processor starting with the metrics data rₛ stored in the respective LM and extrinsic information stored in the associated respective I-REG register bank. By the time the first element of updated extrinsic information becomes available at each of the processors 605, . . . , 650, these N elements of updated extrinsic information will be available to be deinterleaved by sending each respective element of updated extrinsic information for a pass of OBC SISO decoding associated with a respective target codeword of the outer code B. In accordance with the exemplary embodiment 600, these N elements of updated IRCC SISO decoding extrinsic information elements are preferably passed via their respective optional IRCC SISO decoding input/output (I/O) registers 630, . . . , 645. Each of these N elements of updated extrinsic information will be sent in a parallel transfer cycle to a target respective location in a respective target one of the O-REG register banks 620, . . . , 660. To achieve this, these N updated elements of extrinsic information are passed via the INASL 635 under control of a set of control signals that cause the INASL 635 to apply the pre-determined CI-2 inverse permutation function (i.e., de-interleaving operation 520) to these N elements of updated extrinsic information. Each time a new group of N updated extrinsic information elements becomes available from the N processors while performing IRCC SISO decoding, these N updated elements of extrinsic information are preferably passed through the INASL block 635 to their respective target locations in their respective target ones of the O-REG register bank 620, . . . 660. By the time the last updated elements of updated extrinsic information are supplied by N processors while performing IRCC SISO decoding on their respective subsequences of IRCC extrinsic information and metrics data, these last elements of updated extrinsic information are passed through the INASL 635 and inserted into the final respective target locations of the O-REG register banks 620, . . . , 660 to complete the parallel implementation of the CI-2 permutation function (i.e., deinterleaving 535). By the time the IRCC SISO decoding completes, the updated extrinsic information will be in place in the O-REG banks 620, . . . 660 so that the processors 605, . . . 650 will have the data they need to begin the next pass of OBC SISO decoding 525.

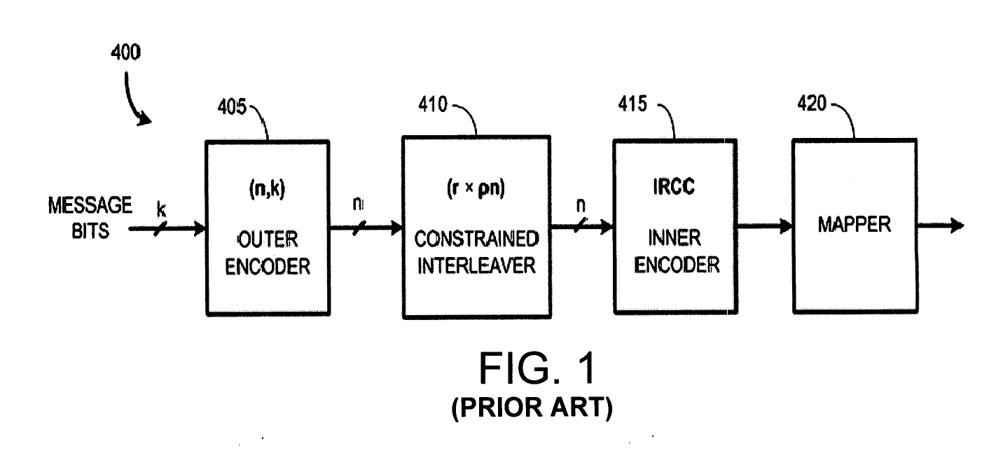

Next each of the processors 605, . . . , 650 performs OBC SISO decoding in parallel to update the extrinsic information related to respective codewords assigned to each respective processor. As discussed below, parallelism available at the CTBC code SISO decoding iteration level is preferably exploited by each of the processors 605, . . . , 650 using multiple functional units and instruction level parallelism where applicable. Once the processors have updated their respective first elements of extrinsic information, the N processors, 605, . . . , 650, couple their respective elements of updated extrinsic information via the INASL 635 to the respective OBC SISO decoding input/output (I/O) registers 625, . . . , 640. The contents of the registers 625, . . . , 640 are then passed through the INASL 635 which applies the predetermined and fixed CI-2 permutation function to these N elements of updated extrinsic information in order to begin a parallel implementation of the constrained interleaving 535. Each respective output of the INASL 635 passes via the optional I/O registers 630, . . . , 645 and is routed to a respective target address location of a respective target one of the I-REG register banks 615, . . . , 665. Each time N newly updated elements of extrinsic information become available from the N processors performing OBC SISO decoding, these N extrinsic information elements are passed through the INASL block 635. By the time the last N elements of updated extrinsic information are supplied by the N processors while performing OBC SISO decoding, these last N elements of updated extrinsic information are processed through the INASL 635 and inserted into their respective final target locations of their respective target one of the I-REG register banks 615, . . . , 665. The CTBC code SISO decoding iterations of this paragraph and the preceding paragraph are carried out until the stopping criterion 530 is met. As discussed before, the stopping criterion can be as simple as waiting until a fixed number of CTBC code SISO iterations 500 have been completed. Once the stopping criterion has been met a set of decoded message bits are preferably output from the N processors. For example, the N processors can make hard decisions and output this information in the natural ordering of message bits in the OTN frame or similar frame of message bits encoded by the CTBC encoder of FIG. 1 via one or more an interconnection network paths that couple each of the N processors to a common decoded message bit output port (not shown in FIGS. 3, 8 and 10 but such output sequencing and optional output data port of the INASL is present in most embodiments of the present invention).

In accordance with an aspect of the present invention, the stopping criterion 530 as specifically used in CTBC code SISO iterations 500 can be modified to perform an additional function. Expanding upon the prior art ideas of U.S. Pat. No. 8,532,229, which is incorporated by reference herein, it is contemplated as an aspect of the present invention to use a maximum likelihood (ML) based stopping criterion as a part of the stopping criterion 530, which can be executed in a distributed fashion on the processors 605, . . . , 650, on a codeword by codeword basis, of the outer code B. In embodiments of the present invention that use this aspect of the invention dealing with an expanded stopping criterion 530, the stopping criterion 530 can be viewed as being applied at each processor 605, . . . , 650 as each processor 605, . . . , 650 works its way through OBC SISO decoding on the one or more codewords assigned to the processors 605, . . . , 650. In general, the improved stopping criterion is preferably applied during OBC SISO decoding whose starting extrinsic information has been supplied by a previous pass through of IRCC SISO decoding. In accordance with the improved stopping criterion aspect of the present invention, the OBC SISO decoding can optionally be augmented by a stopping criterion like the one of block 530. The stopping criterion used during OBC SISO decoding is applied to each candidate codeword being evaluated during OBC SISO decoding. The stopping criterion is preferably configured to determine if a given candidate codeword appears to be converging to a valid codeword in the ML (maximum likelihood) sense. An ML based metric is computed to evaluate whether a candidate codeword being analyzed (e.g., during Pyndiah decoding, reduced complexity Pyndiah decoding, OSD, or the like) to help guide towards a valid codeword of the entire CTBC code in the ML sense. If a candidate codeword indicates a high score according to the OBC SISO decoding algorithm in use, but when this same candidate codeword is compared to other candidate codewords in the ML sense and found to have a low score in the ML sense, the extrinsic information for this candidate codeword is preferably reduced or set to zero. By reducing or setting the OBC SISO decoding updated extrinsic information to zero, this candidate codeword will be pruned out by the OBC SISO decoding algorithm. That is, the added ML based stopping criterion checking can potentially reduce the error rate associated with CTBC coded SISO iterative decoding. This aspect of the present invention is optional and is general in the sense it can be carried out on any of the system embodiments 600, 800 and 1000 as described herein, as well as any other processing architecture, to include a single processor architecture, that sequentially carries out CTBC code SISO iterative decoding 500.

Consider the exemplary embodiment discussed above where the outer code B is a (72, 64) shortened BCH code (n=72), the IRCC is a rate-1 accumulator, and the parameters ρ=239, L=8 are used so that CI-2 frame size is ρLn=239*8*72=137, 664. Each processor performs OBC SISO decoding 525 on K≧1 codewords of the outer code B, and in this exemplary embodiment, set K=1 so that the number of processors, N, is given by N=ρL/K=239*8/1=1912. In this specific exemplary embodiment of the system 600, each of the I-REG register banks 615, . . . , 665 will be configured to hold n=72 elements of extrinsic information. With this configuration, IRCC SISO decoding of the 1912 different 72-element subsequences is preferably performed in parallel on the N=1912 processors. As each N words of updated IRCC SISO decoding extrinsic information become available, they are passed through the INASL 635 and stored in their respective target locations in their respective target ones of the O-REG register banks 620, . . . , 660 in accordance with the inverse of the CI-2 permutation function used in the CTBC code of the present embodiment. As soon as the last N words of updated IRCC SISO decoding extrinsic information are output from the N processors and are passed through the INASL 635, the final set of 1912 elements of updated IRCC SISO decoding extrinsic information will have been placed into their respective target locations in their respective target ones of the O-REG register banks 620, . . . , 660 in accordance with the inverse CI-2 permutation function of the CTBC code. Now the N=1912 processors perform an pass through OBC SISO decoding in accordance with outer code B. As each respective set of the N parallel words of the updated extrinsic information become available, they are passed through the INASL 635 to be placed in a respective target location of a respective target one of the I-REG registers 615, . . . , 665 in accordance with the CI-2 permutation function of the CTBC code being decoded. The process is repeated to implement the decoding of FIG. 2 using the system of FIG. 3.

Next consider a second exemplary embodiment, similar to the exemplary embodiment as just considered above, designed to decode the same CTBC code, but this time where K=8 codewords of the outer code B are computed on each one of the processors 605, . . . , 650. The number of processors, N, in FIG. 3 is thus preferably reduced from N=ρL/K=239*8/1=1912 to N=ρL/K=239*8/8=239. Such a reduction may be needed due to VLSI area constraints, for example. In this second exemplary embodiment, each of the I-REG register banks 615, . . . , 665 and each of the O-REG banks 620, . . . , 660 will need to hold K*n=8*72=576 elements of extrinsic information. Therefore, the INASL 635 will require K=8 times as many parallel transfer cycles to perform the CI-2 permutation and inverse permutation operations. However, the implementation of the INASL 635 will require roughly K times fewer ports. Also the data path configurations and data transfer sequencing in the INASL 635 in this example will differ from the previous example. It is contemplated by the present invention that the design of the processors 605, . . . , 650 could be designed differently depending on the number of processors in a given embodiment of the system 600. For example, when fewer processors are used (e.g., N/8 versus N), each processor could optionally be designed to apply more iteration-level parallelism and/or more instruction level parallelism, or could implement a more powerful application-specific instruction set to further speed up instruction level processing. Also, the processors 605, . . . 650 could be designed to have additional functional units or even two or more processor cores to work on different codewords and/or subsequences of information at the same time.

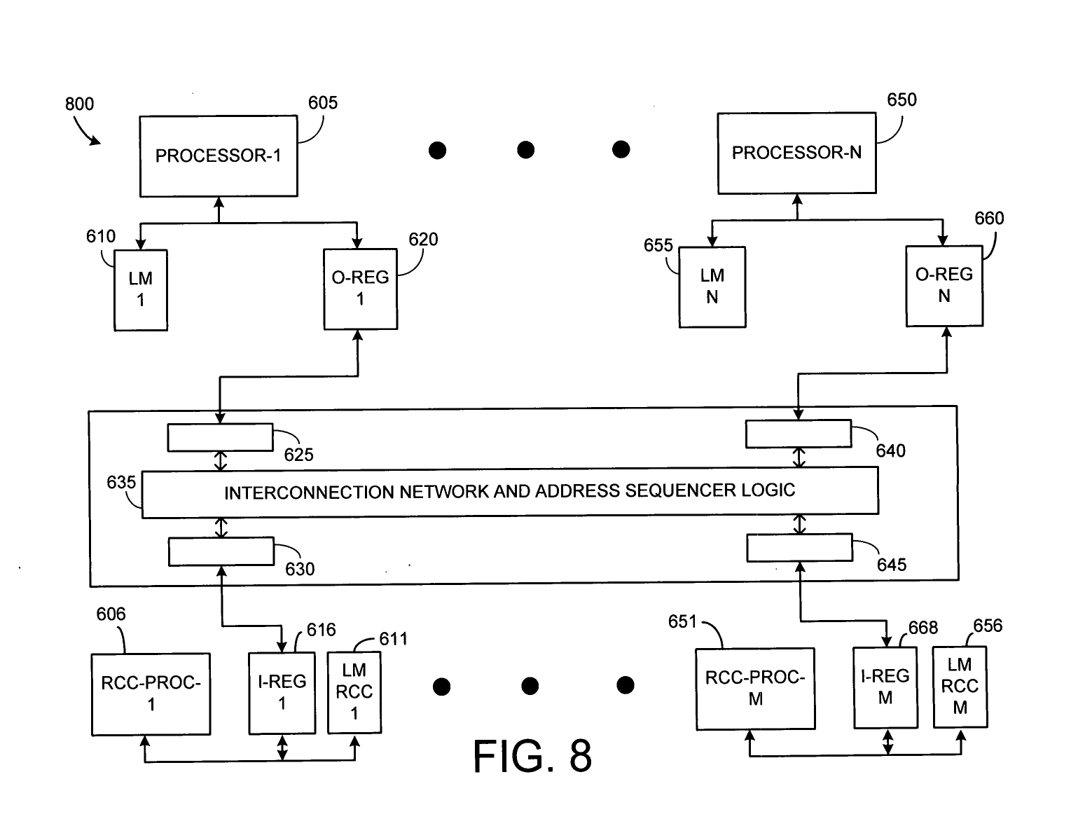

In operation, the rₛ metrics vector is assembled based on received information from a communications channel as per block 505. The rₛ metrics vector is preferably sent from channel interface unit to one or more received signal metrics calculation units (not shown in FIGS. 3, 8, and 10). An input signal distribution unit (not shown, but preferably deployed in each of the exemplary systems 600, 800, and 1000 and their alternative embodiments) is coupled to receive digitized information related to the input signal, r(t), and to distribute this information for use by the processors 605, . . . , 650 (or the processors 606, . . . , 651 in the system 800). The received signal, r(t), represents a received version of a CTBC coded signal that has been generated and transmitted in accordance with any particular specific embodiment of FIG. 1. The received signal, r(t), is typically also corrupted by channel noise and in some cases channel distortion, polarization fluctuations, and demodulation related effects such as timing and/or phase recovery jitter, and/or other impairments. The input signal distribution unit is configured to cause to be distributed N respective subsequences of digitized elements of received signal input information to N respective memory banks, such as the local memory banks 610, . . . , 650. In embodiments where M≦N separate processors are used to perform IRCC SISO decoding (as discussed below in connection with FIG. 8), the input signal distribution unit will send M subsequences of received signal input information to M respective memory banks. The phrase “digitized received signal input information” encompasses any type of digitized information representative of the digitized input signal, r(t). For example, the digitized received signal input information could be any of digitized samples of r(t), bit metrics associated with r(t), or any type of received signal metric associated with the input signal, r(t). Also, the phrase “received signal metric” is general and encompasses bit metrics as well as any other type of received signal metric.

In the system 600, the digitized input signal information is normally distributed for storage in local memories 610, . . . 655 (in the system 800 the input signal information is normally distributed to the local memories 611, . . . , 656). If the local memories are implemented as multiport memories, they are typically the target location for the information distributed by the input signal distribution unit. If the input signal distribution unit can pass the digitized input signal information through an input port of the INASL 635 for distribution directly to the target local memories. If the local memories are not multiport memories, then, for example, the digitized input signal information can be passed to the I-REG register banks 615, . . . 665 (or 616, . . . , 668 in FIG. 8). The processors 606, . . . , 650 (or 606, . . . , 651 in FIG. 8) can move (e.g., via streaming on the processor-side port of the I-REG register bank) their respective subsequence of digitized input signal information to their local memory. In embodiments where input signal sample information is distributed and the processors compute the received signal metrics in parallel, the computation of the received signal metrics is performed prior to storage of the received signal metrics in the local memory. Also, many OBC SISO decoding will need the received signal metrics on a codeword by codeword basis. Therefore, in embodiments where the input signal distribution unit did not already write the received signal metrics to the I-REG register bank or a multiported local memory, the processors also preferably write the received signal metrics to the I-REG register banks. At this point the INASP 635 performs constrained deinterleaving of the received signal metrics and transfers the received signal metrics to the O-REG register banks. Then the processors preferably move the contents of the O-REG register banks to the respective local memory, thereby saving a copy of the received signal metrics both in the order needed for IRCC SISO decoding and for OBC SISO decoding. After this, the memory locations in the I-REG register banks and/or the O-REG register banks can be set to zero to initialize the first respective pass through IRCC SISO decoding and/or OBC SISO decoding. Such embodiments are desirable because they limit the number of multiported memories, which are more complex to implement in VLSI than a single ported memory (or, equivalently, register bank). Hence it is to be understood that the present invention generally contemplates the distribution of the input signal information to the processors for subsequent use in CTBC code SISO iterative decoding.

In some embodiments, the raw data from the demodulated version of r(t) is distributed, in natural input order, as N subsequences of information to the N processors 605, . . . , 650 which of each will then calculate a respective subsequence of the rₛ metrics vector. The j^{th} subsequence of the rₛ metrics vector optionally computed at the j^{th} processor, Pⱼ, corresponds to metrics needed in for IRCC SISO decoding on the processor, Pⱼ. Once computed or received, the processors 605, . . . , 650 couple each of these received signal metrics for distribution through the INASL 635 to preferably also be stored in target locations in the local memories 610, . . . , 655 in accordance with the CI-2 inverse permutation of the rₛ metrics 510 so as to be in position for subsequent OBC SISO decoding operations that will need a respective subsequence of the rₛ metrics vector corresponding to the K codewords to be used in OBC SISO decoding operations on each respective processor, Pⱼ. It can be noted that while the received signal metrics are computed in an ordering that corresponds to the CI-2 ordered IRCC information, the CTBC code SISO iterative decoding output read out of the system 600 in codeword order when the processors 605, . . . , 650 finish their final pass of OBC SISO decoding. In any of the systems 600,800,1000 and any of their equivalents and variants can optionally include (not shown) an input processor and/or an input port and/or an output processor and/or an output port. Such port(s) could be provided as extra channels of the INASL 635, for example.

The CI-2 inverse permutation of the rₛ metrics 510 is preferably executed on the INASL 635 in parallel with (at the same time as) the processors 605, . . . , 650 beginning a first pass through IRCC SISO decoding. IRCC SISO decoding of the N=239 different 576-element subsequences is performed in parallel on the N=239 processors. As each N=239 words of extrinsic information becomes available, these words of updated IRCC SISO decoding extrinsic information are passed through the INACL 635 and stored in a respective target register location in a respective target one of the O-REG register banks 620, . . . , 660. As soon as the last N words of updated IRCC SISO decoding extrinsic information are output from the N processors, these N words of IRCC SISO decoding extrinsic information are passed through the INASL 635 so that each respective one of final set of N=239 updated elements of extrinsic information will have been placed in a respective target location in each of their respective target one of the O-REG register banks 620, . . . , 660. Next, the N=239 processors operate in parallel to perform an pass through OBC SISO decoding, but do so for K=8 different independent codewords of the outer code B. As each group of N elements of updated extrinsic information becomes available, this group of extrinsic information elements is passed through the INASL 635 so that each respective element of updated extrinsic information is placed into a respective target location of a respective target one of the I-REG register banks 615, . . . , 665. Similar to the previous example, the entire above process is repeated to perform SISO iterations in accordance with FIG. 2 until the stopping criterion 530 is met.

From the two specific examples above, it can be seen that as many as N=ρL processors can be efficiently used (kept busy) in the system 600 while performing CTBC code SISO decoding. The number of processors can be reduced in order to balance speed requirements and available VLSI resources such as area, power consumption and the like. When fewer processors are used, if VLSI area resources permit, each processor can be designed to be more powerful by taking more advantage of various types of parallelism as discussed above.

FIG. 4 illustrates an exemplary embodiment that illustrates one way the INASL 635 can be architected. The INASL 635 preferably implements interconnection functionality provided by a pair of an N-to-N cross bar switches 670, 680, that collectively provide bi-directional connection between the N registers 630, . . . , 645 and the N registers 625, . . . 640. As also shown in FIG. 4, the INASL 635 is preferably architected to support the buffering functionality of a set of output buffers 675, 685. In response to sets of control signals the interconnection networks 670, 680 can support N-to-M mappings where M≦N, and multiple ones of the N inputs can be mapped to a selected one of the M channels used in the N-to-M parallel transfer cycle. That is, while implementing the CI-2 permutation function and inverse permutation function pair, whenever a parallel transfer cycle requires that N data elements need to be mapped to M<N output ports, each of the M output ports can optionally include a FIFO channel within the output buffers 675 or 685. This allows multiple elements of extrinsic information to be mapped to a selected M<N number of output ports. When more than one element of updated extrinsic information is mapped to a single port of the optional output buffer 675 during a given INASL 635 parallel transfer cycle, the INASL 635 will sequence the contents of each the corresponding output buffer into a set of pre-defined target locations in the corresponding I-REG or O_REG register bank associated with the appropriate target processor. The order of the sequencing of the data out of the output buffer 675 can be a FIFO ordering or can be a permuted ordering. That is, INASL 635 can implement the CI-2 permutation function and inverse permutation function pair by using the N-to-N interconnection network 670 to perform a first stage of parallel interleaving and can use the ordering of the sequencing of the output buffer 675 to perform a second stage of interleaving. While FIG. 4 shows separate forward and backward buffered interconnection networks, in specific embodiments, parts or all of the interconnection networks 670, 680 and their output buffers 675, 685 could be merged and reused on a time-multiplexed basis. That is, any of the embodiments described herein can be designed to operate in a half-duplex mode. Through the use of appropriate multiplexers, demultiplexers, gates, registers, and/or tri-state bus drivers, much of the hardware of the blocks 670,675,680, and 685 can be designed for bi-directional operation to implement the functionality of the separate forward and reverse data paths shown in the upper and lower portions of FIG. 4.

The INASL 635 as shown in FIG. 4 is representative of a family of architectural implementations. For example, each output path of the interconnection network 670 can implement each respective portion of the output buffer 675 as one of more of the registers (or register sets) 625 . . . 640. Also, the interconnection networks 670 and 680 can be implemented as multistage interconnection networks as are known in the art. Such networks can be designed to supply the same functionality as an N-to-N crossbar switch, but typically using more clock cycles with much more efficient use of VLSI hardware area-related resources. In such embodiments, or in crossbar switch embodiments, the interconnection networks 670, 680 can be designed with internal embedded register buffering and/or hidden nodes and the like to provide internal buffering functionality 675 685, to allow contention to be avoided, and/or to allow hardware reuse of the interconnection data paths in a multistage interconnection implementation with registered feedback. In such alternative embodiments, the function of the output buffers can be merged with the interconnection networks 670, 680 in order provide the same or similar result. Also, in other alternative embodiments, the functionality of the output buffers 675, 685 can be moved to the multi-ported I-REG and O-REG register banks. More details of the implementation of the INSAL 635 are provided in connection with FIG. 5.

From FIG. 3 and FIG. 4 it can be seen that the INASL 635 supports switched/buffered data paths in both the forward (inner-to-outer code) and reverse (outer-to-inner code) directions. For example, the upper half of FIG. 4 shows the forward direction paths and the bottom portion of FIG. 4 shows the reverse direction paths. In the forward direction, the INASL 635 implements the fixed and predetermined CI-2 inverse CI-2 permutation function (CI-2 de-interleaving). In the reverse direction, the INASL 635 implements the fixed and predetermined CI-2 permutation function (CI-2 interleaving). Without loss of generality, FIG. 5 focuses on the upper half of FIG. 4, i.e., the forward path through the INASL 635. The same discussion and analysis provided in connection with FIG. 5 can be readily understood by one skilled in the art to also apply to the design and implementation of the reverse path as shown at the bottom half of FIG. 4.

FIG. 5 shows an exemplary embodiment of the forward path portion of the INASL 635. FIG. 5 and the discussion thereof and the concepts related thereto are understood to also apply to the specific design and implementation details of reverse path shown at the bottom of FIG. 4. During forward path operation, the inputs to the INASL 635 are the N input registers 630, . . . , 645 that collectively receive N updated elements of IRCC SISO decoding extrinsic information from the N different processors of FIG. 3, either in the same clock cycle, or at substantially close times. As discussed earlier, although not shown in FIG. 3, the registers 630, . . . , 645 can optionally be implemented as registers in the multi-port I-REG banks 615, . . . , 665. The registers 630, . . . , 645 can also be implemented as processor accessible registers, processor port registers, or as input registers that are a part of the INASL itself. This last option is preferably used, for example, when the interconnection network 670 (and/or 680) is implemented as a multistage interconnection network with registered buffering between stages and/or within the stages. In some cases, a mesh of trees or similar interconnection network can be used to provide hardware efficient contentionless access through interconnection network 670. In some embodiments, a set of registers is used in a multistage network in a feedback configuration so that the multistage network can reuse a given interconnection network stage to implement a multistage interconnection network in multiple register-clocking clock cycles.

FIG. 5 generally shows a set of N inputs 630, . . . , 645 that come from N processors 605, . . . , 650. These inputs are coupled into an N-to-N interconnection network 670 (or 680 in the reverse direction). The N-to-N interconnection network 670 is coupled to a output buffer 675. The output buffer registers 675 can be implemented as FIFO (first in-first out) buffers, random access address-sequenced buffers (i.e., can be output-sequenced to implement a second stage of permutation in conjunction with the N-to-N interconnection network 605), or in other configurations, the output buffers 675 can be embedded into the design of the N-to-N interconnection network 605. In many alternative embodiments, the forward path embodiment shown in FIG. 5, a subset containing more than one of the N input data elements that pass through the interconnection network 670 in a given parallel transfer cycle can be coupled via a switchable and optionally registered data paths to a particular target one of the output buffers 675. This subset of elements can then be written into a respective subset of target locations in a respective one of the outer code multi-port register (or memory) banks 620, . . . , 660 associated with the particular target one of the output ports.

While cross bar switches are very fast, versatile and contention free, they require a relatively large amount of VLSI resources to implement. Less resource intensive interconnection network architectures can also be used to implement the N-to-N interconnection network 670. As is known in the art of parallel processing, the N-to-N interconnection network 670 (and/or 680) can optionally be implemented as a multistage interconnection network. Examples of multistage interconnection networks include hypercube networks, shuffle-exchange networks, Banyan networks, Delta networks, Omega networks, mesh of tree networks, and other interconnection network topologies known to those of skill in the art of parallel processing architectures. In some cases registers can be used in a feedback configuration in the interconnection network 670 to allow one or more stages of the multistage interconnection network to be reused, thus reducing hardware complexity. Multistage networks can use register buffering between one or more of the stages. Internal hidden nodes can also be used to provide contention free parallel data transfers and to speed up N-to-M parallel transfer cycles where M<N and multiple data elements traverse data paths to selected ones of the M outputs in the parallel transfer cycle.

Hence it is to be understood that the current invention contemplates as a first step in implementation that a designer will select an appropriate interconnection architecture that meets a prescribed set of speed requirements while also reducing or minimizing the hardware, layout, bussing, data paths, buffering and control aspects of the interconnection network 605, 610 to specifically implement the CI-2 permutation function and inverse permutation function pair to support de-interleaving 510, 520 and interleaving 535 used during the SISO decoding of the CTBC code as described herein.

The interconnection network 670, the output buffer 675, and the outer code extrinsic information registers 620, . . . , 660 are all preferably controlled by the output of a very long instruction word (VLIW) memory 690. The contents of the VLIW memory 690 are written out of the VLIW memory 690 in accordance with address inputs received from an instruction counter sequencer 695. In some embodiments, one or more optional feedback paths are implemented to move one or more bits of information from the contents of the VLIW memory 690 back to the instruction counter and sequencer 695. This feedback path can be used to provide certain aspects of the functionality of a micro sequencer, a state machine, a microcoded state machine or any variation thereof. In some alternative embodiments, these one or more feedback paths pass straight from the VLIW memory data output to one or more VLIW memory address input lines. In other alternative embodiments the feedback information is processed by the instruction counter sequencer 695 in order to determine the next VLIW memory address to be used to generate the next set of control inputs for an upcoming clock cycle or to be propagated through set of pipelined control paths where different phases successive VLIWs execute in different pipelined stages of the instruction processing aspect of the VLIW portions of the INASL 635.

In another form of alternative embodiment the functions of the VLIW memory 690 and the instruction counter sequencer 695 are merged into a microcontroller state machine 690, 695. The microcontroller state machine 690, 695 embodiments can be viewed as one or more pattern generator state machines. Such embodiments can be configured to generate a set of states whose state outputs correspond an equivalent sequence of VLIWs. A pattern generator state machine is a state machine that sequences through a number of states (e.g., each VLIW address input from the instruction counter sequencer can correspond to a state in the state machine) to generate a sequence of control outputs that, in the case of the INASL 635, provide a sequence of interconnection network configuration control inputs to the interconnection network 670 and FIFO clocking control inputs to the output buffers 675 to implement a sequence of as many parallel transfer cycles as are needed to implement the inverse CI-2 permutation function as illustrated by the top half of FIG. 4 and the CI-2 permutation function as illustrated by the bottom half of FIG. 4. The sequencer keeps periodically and deterministically alternating between the inverse CI-2 permutation function and the CI-2 permutation function over and over again as SISO iterations continue to be carried out by the system 600 in real time. That is, the pattern generated by the pattern generator as the sequencer executes is a fixed known pattern comprising the sequence of bits corresponding to the sequence of VLIWs output from the VLIW memory 690 in order to implement the CI-2 permutation function and inverse permutation function pair on the INASL 635 as a sequence of forward and reverse direction parallel transfer cycles.

The VLIW memory 690 and the instruction counter sequencer 695 and/or the microcontroller state machine 690, 695 embodiments can optionally be implemented as a distributed controller. For example, in many preferred embodiments, for a given switching fabric in the N-to-N interconnection network 670, each switching element will always cycle through the exact same set of switch settings periodically as each SISO iteration is executed. Likewise, all of the clocking of data in and out of any internal registers in the switching fabric and/or all of the all of the control signals sent to each output buffer 675 and all of the O-REG register bank address sequences and multiport register bank control signals will be identical each SISO iteration. Therefore, the VLIW memory 690 functionality need not be implemented as a single centralized VLIW memory. Rather, the VLIW memory 690 functionality and the instruction counter sequencer 695 functionality and/or the pattern generator state machine embodiment functionality can be physically distributed over the VLSI system 600 to store and/or generate the sub-patterns of control signals for different switching elements, registers, output buffers, as well as addressing and control sequences for any or all of the local memories 610, . . . , 655, the multi-ported register banks 620, . . . 660 (and the I-REG banks 615, . . . , 665). This type of distributed control architecture preferably cycles through the periodic control signals that are used over and over by the INASL 635. Such embodiments are often preferred because they generally allow the VLSI system 600 to run at a higher clock speed by eliminating longer paths for control signals that would alternatively emanate from a central location on the VLSI system 600. Any such type of distributed implementation of the functionality of the VLIW memory 690, the functionality of the instruction counter sequencer 695, or the functionality of the pattern generator state machine embodiment 690, 695 are optional.

The optional P-flags are provided to maintain synchronization between the processors and the INASL 635. The optional P-flags preferably indicate to the INASL 635 each time a next set of N elements of data are ready for transfer. A parallel transfer cycle is carried out each time the next set of N elements of data is ready to be passed to a corresponding set of target interleaved or de-interleaved destinations. In response to the P-flags and in response to the point in the SISO iteration sequence when the next set of data elements become available, the INASL 635 executes a respective parallel data transfer cycle to move this particular set of data elements to their target locations in accordance with the CI-2 permutation function or the CI-2 inverse permutation function. The P-flags can also optionally include reverse direction flags that indicate to the processors when the INASL 635 has completed its last parallel transfer cycle of a CI-2 permutation function or CI-2 inverse permutation function. The P-flags can also act as semaphores to control access to the multiport I-REG and O-REG register banks.

The P-flags are optional because the system 600 can be implemented with a form of control whereby synchronization between the processors 605, . . . 650 and the INASL 635 is implicit due the presence of a predetermined synchronized instruction sequences feeding to both the processors 605, . . . 650 and the INASL 635. The processors and the INASL can thus be implicitly aware each other's operations by simply executing their respective instructions. For example, in such embodiments, the VLIW memory 690 may be considered to include additional fields that supply SIMD instructions to the processors 605, . . . , 650. As discussed earlier, the physical implementation of the VLIW 690 memory functionality can be distributed over different areas of the VLSI system 600, so the SIMD instruction source for the processors 605, . . . 650 and the source of the VLIWs used by the INASL 635 need not be implemented in a single memory device, but may be distributed and operated in clock synchronization. In such embodiments, the INASL 635 is viewed as a global data movement processor that operates in parallel with the arithmetic logic oriented processors 605, . . . , 650 that operate under a processor SIMD field of the VLIW.

In a preferred embodiment, by way of example, consider the case where the P-flag(s) indicate to the instruction counter sequencer 695 that N elements of updated extrinsic information are currently available, one each from each of the N processors. In this example, the P-flag(s) mark the beginning of each parallel transfer cycle. That is, the P-flags act as a ready-to-send flag to indicate to the INASL 635 to begin to carry out a parallel transfer cycle. The instruction counter sequencer 695 preferably includes state machine logic that provides a sequence of VLIWs that are used to carry out each particular parallel transfer cycle. Alternatively, tag metadata can be included with each of the N data words to be transferred in a parallel transfer cycle. This alternative type of embodiment uses distributed data-tag-driven control within the switching fabric of the INASL 635. The INASL 635 can be designed to be responsive to tag metadata that may include a destination port and/or destination address in a target multiport register bank. Such design choices are available to the VLSI designer, all in accordance with various embodiments of the present invention. However, a preferred embodiment avoids the need to use tag metadata in the switching fabric of the INASL because a predetermined set of distributed VLIWs generated in any of the ways discussed above would appear lead to a more efficient embodiment in terms of VLSI resources.

Because of the pseudo randomization operations involved in the CI-2 design process, it can be observed that the CI-2 permutation function produced in accordance with the CI-2 design rules for a given sized constrained interleaver design matrix is non-unique. Hence an aspect of the present invention contemplates several alternative embodiments to modify and/or implement the CI-2 permutation function to reduce or completely avoid output contentions as discussed above. Such design procedures can be used to reduce or completely eliminate the need for the above-discussed output buffering 675, 685. Also, such design procedures can be used to reduce or eliminate the portions of the addressing and sequencing logic in the INASL 635 used to control the output-contention handling and/or control of the output buffers 675, 685 in FIGS. 4 and 5. Hence another aspect of the present invention provides design techniques for CI-2 interleavers to reduce or avoid output contentions and buffering requirements in the INASL 635. As discussed in further detail below, the present invention also contemplates that the instructions sent to the processors 605, . . . , 650 can be programmed to modify the order in which the processors update and output their extrinsic information outputs. Such modified output orderings can be designed allow the system 600 to implement any valid CI-2 permutation function in such a way as to reduce, further reduce, or completely eliminate output contentions. Efficient embodiments of the INASL 635 can thus be preferably designed to be free of output contentions by optimizing the CI-2 permutation function design process to reduce or eliminate output contentions, and some simple logic in the processors can be used to ensure that output contentions are completely avoided.

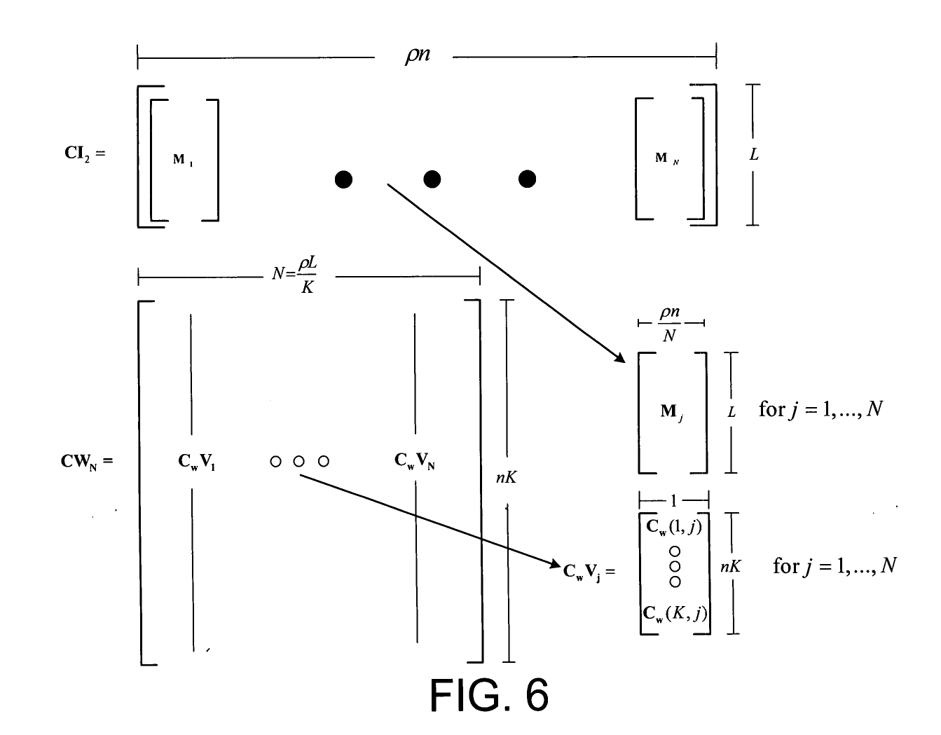

Referring now to FIG. 6, Let CI₂εB^{L×ρn} be a CI-2 design matrix that was designed in accordance with the CI-2 design rules. Let CW_{N}εB^{nK×N} be a codeword matrix where each of the N columns of this matrix contains K n-bit codewords per column, e.g., a column vector containing K of the (n,k) outer codewords of the outer code B. In this patent application, the symbol B^{m×n} is specially defined to denote a space of m×n matrices whose elements are coded bits (Boolean bit variables), but further, wherein each element of a matrix in the space B^{m×n} can have associated therewith metadata that corresponds to, for example, a codeword index, e.g., 1≦i_{cw}≦ρL, that identifies a corresponding codeword of the outer code B from which the coded bit belongs, and a bit index, 1≦i_{b}≦n, (e.g., where B is an (n, k) block code and each codeword has n bits) identifying the specific bit position of the coded bit within its corresponding codeword. The metadata associated with each element of the matrix B^{m×n} can also include a set of indices (i_{C1-2},j_{C1-2}) that indicate the location of the coded bit in the CI-2 constrained interleaver design matrix. It is to be understood that the matrix space B^{m×n} is a mathematical concept, and that matrices in B^{m×n} can be defined in various ways using computer data structures that can be configured to contain whatever additional metadata is useful for a given computer aided design software program. Various such computer aided design programs are provided as aspects of the present invention hereinbelow.

The ordering of the codewords in the codeword matrix is arbitrary and is left as a free parameter to the designer. That is, the designer (or automated computer aided design software) can the reorder of the codewords in the matrix CW_{N} as needed as discussed in further detail below in the context of various examples. View the matrix CW_{N} as being partitioned as an N-element row vector whose elements correspond to column vectors, C_{w}VⱼεB^{Kn}=B^{Kn×1}, for j=1, . . . , N. Next view the matrix CI₂ as being partitioned as an N-element row vector of sub-matrices, MⱼεB^{L×ρn/N}, for j=1, . . . , N. With the matrices defined in this way, it can be noted that the j^{th} processor, denoted Pⱼ, will perform the OBC SISO decoding 525 portion of the CTBC code SISO iterations 500 for each of the K n-bit codewords located on the i^{th} column of CW_{N}. Also, this same j^{th} processor, Pⱼ, will perform IRCC SISO decoding 515 for a corresponding K*n-bit subsequence of the IRCC. Recall that the CI-2 interleaved sequence can be viewed as a set of coded bits that are read out of the CI-2 design matrix in column major order. Therefore, processor Pⱼ will perform IRCC SISO decoding on a j^{th} subsequence of the IRCC corresponding to Kn coded bits. The a j^{th} subsequence of containing Kn coded bits of the IRCC will correspond to coded bits in the j^{th} submatrix Mⱼ, when read in column major order. Note that CI₂εB^{L×ρn} and CW_{N}εB^{nK×N} both contain the same number, M=Lρn, of coded bits (and their optional associated metadata), but arranged in different orders in accordance with the CI-2 permutation rule. These matrices highlight which coded bits or elements of extrinsic information will be processed by the j^{th} processor, Pⱼ, during OBC SISO decoding 525 and during IRCC SISO decoding 515 while performing CTBC code SISO iterative decoding 500 on the system 600 using N=ρL/K processors.

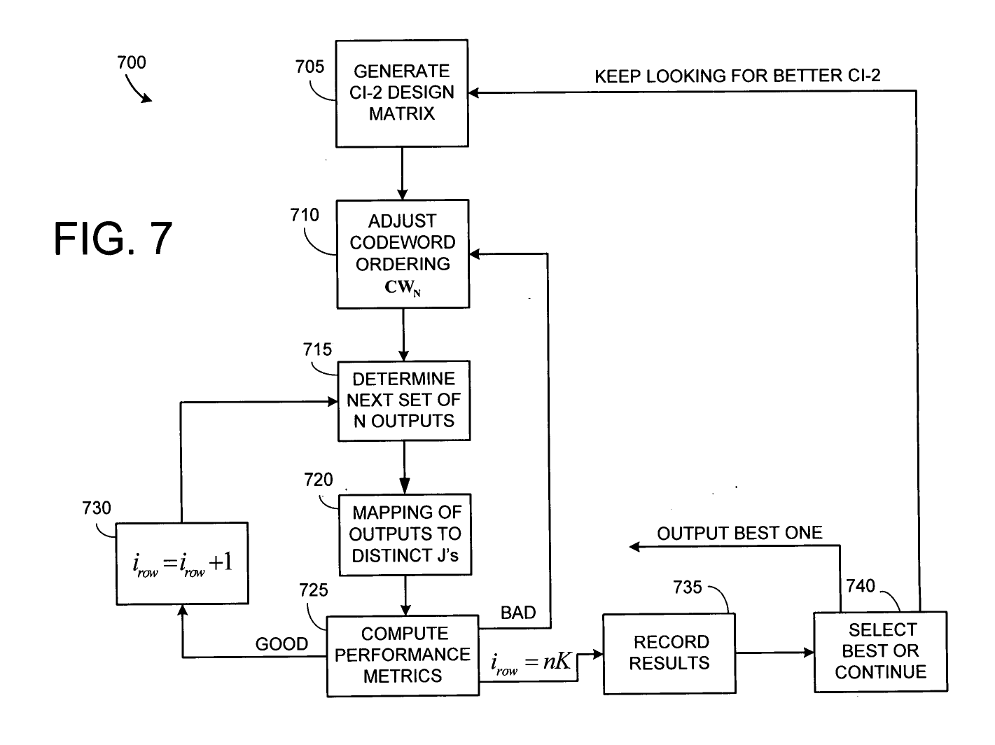

Consider the computer-implementable design method 700 as depicted in FIG. 7. In the discussion that follows, again assume that the system 600 is implemented such that all of the processors 605, . . . , 650 operate in a SIMD mode, i.e., they all work in parallel to update the extrinsic information in their respective I-REG and O-REG register banks, one element at a time, and in lockstep. The design process begins at block 705 by using, for example, a prior art CI-2 design process to design a valid CI-2 permutation function as characterized by a corresponding valid CI-2 design matrix CI₂εB^{L×ρn}. Block 705 thus corresponds to the act of generating a CI-2 design matrix using the prior art design methods or a variation thereof. Assuming a specific CTBC code has been design so that the outer code B and the IRCC are known, and assuming that N=ρL/K processors are available, the design method 700 is configured to determine a way to implement the corresponding CTBC code SISO iterative decoding iterations on the system 600 while reducing or eliminating output contentions (or other types of contentions in the INASL 635 such as internal contentions in the interconnection network 670, 680) and output buffering 675, 685 requirements associated with a sequence of parallel transfer cycles that arise in the INASL 635 during CTBC code SISO decoding.

Given that all the above coding and architectural parameters are known, control next passes to block 710 which optionally reorders the codewords in the matrix CW_{N}. The ordering of the codewords in the matrix CW_{N} merely assigns specific codewords to specific processors for the OBC SISO decoding 525. The j^{th} processor will decode the K codewords in the column vector C_{w}Vⱼ. It is observed that different assignments of codewords to different ones of the N processors will give rise to different interconnection requirements and physical multichannel permutation data paths/switching configuration patterns and sequences. Therefore, the block 710 is provided to allow a computer automated design program to step through various assignments of codewords and to select specific assignments of groups of K specific codewords to be decoded on each of the N processors. By systematically or pseudo randomly stepping through different assignments and orderings of execution of codewords to the processors, certain assignments that give rise to undesirable amounts of output contentions can be avoided, and a certain assignment that is especially desirable can be identified. As discussed above, typically, 1≦K≦L.

Once a candidate ordering of codewords has been selected as per block 710, block 715 determines a set of N output values of extrinsic information that will need to be passed through the INASL 635 in a given parallel transfer cycle. For example, assume that during the parallel processing of the OBC SISO decoding 525, that each processor computes in the computerized order: for i_{cw-p}=1, . . . K, for i_{b}=1, . . . , n, where i_{cw-p} can be viewed as a loop counter for indexing through the K codewords assigned to each of the N processors. With this natural loop ordering, then, each parallel transfer cycle can be viewed as transferring all of the elements of row i_{row}=K*i_{cw}+i_{b}, of the CW_{N} matrix to their respective destinations in the CI₂ constrained interleaver design matrix. Next, block 720 determines a set of possible (e.g., all remaining) target locations in each of the submatrices Mⱼ where the coded bits on row i_{row}=K*i_{cw}+i_{b} of the CW_{N} matrix involved in the bits of all particular codewords will be mapped in accordance with the CI-2 permutation function. An output contention event occurs whenever two or more coded bits on row i_{row}=K*i_{cw}+i_{b} of the CW_{N} matrix map to any single submatrix Mⱼ. Note more than one such event can occur on any given mapping of the row i_{row}=K*i_{cw}+i_{b} of the CW_{N} matrix to the CI₂ constrained interleaver design matrix. The “depth” of each output contention event that occurs at the input to the I-REG bank at processor Pⱼ is defined as the number of elements that map from row i_{row} to the submatrix Mⱼ.

The above-mentioned metadata associated with the elements of the CW_{N} and/or CI₂ matrices can be used to identify output contention events by a block 720. The block 720 can analyze the CI-2 destination metadata (i_{CI-2},j_{CI-2}) associated with each element of each coded bit on row i_{row}=K*i_{cw}+i_{b} of the CW_{N} matrix. By looking at the number of occurrences of each j_{CI-2} associated with of each coded bit on row i_{row}=K*i_{cw}+i_{b} of the CW_{N} matrix, the block 720 can identify each output contention event associated with mapping this row i_{row}=K*i_{cw}+i_{b} of the CW_{N} matrix to the CI₂ matrix. The block 720 can thus also optionally determine the depth each output contention event (i.e., the needed buffer length at the j_{CI-2}^{th} port of output buffer 675 during the i_{row}^{th} parallel transfer cycle). The block 720 can preferably records for each parallel transfer cycle, indexed according to ihd row=1, . . . , nK, any or all of: 1) the j=j_{CI-2} locations of the output contention events, 2) the number of the output contention events, and 3) the depths of each of the output contention events.

In a preferred embodiment the block 720 performs an additional function by transforming the CI₂ matrix to different CI₂ matrix that has a corresponding modified CI-2 permutation function that reduces or eliminates output contention events. This can be achieved because the present invention observes that the CI-2 design matrix involves pseudo randomizations and is thus non-unique. Also, the present invention observes that the CI-2 design process places specific coded bits in specific locations in the CI-2 design matrix, but the bit index into the codeword can be changed between any two coded bits from the same codeword in the CI-2 constrained interleaver design matrix without violating the CI-2 design rules. Therefore, the an aspect of the present invention defines a transformation, T^{(1, 2)}: CI₂⁽¹⁾→CI₂⁽²⁾, which can be implemented by one or more bit swaps between coded bits of any respective same codeword, and such bit swaps can be performed for any or all codewords. The transformation, T^{(1, 2)}, can be used to represent a transformation corresponding to any sequence of such bit swaps among coded bits of respective same codewords. Also, multiple different transformations can be defined, e.g., T^{(1, 2)}: CI₂⁽¹⁾→CI₂⁽²⁾ and T^{(2, 3)}: CI₂⁽²⁾→CI₂⁽³⁾, and these transformations can be cascaded as many times as is convenient, for example, T^{(1, 2)}T^{(2, 3)}=T^{(1, 3)}:CI₂⁽¹⁾→CI₂⁽³⁾.

Using the above observations, the block 720 can preferably also be programmed to reduce or completely resolve output contentions by applying as many of the above transformations as are needed to reduce the number and/or depth of output contention events, or to eliminate all of the output contention events associated with a given parallel transfer cycle. For example, suppose that the metadata associated with three coded bits from the I_{row}^{th} of the CW_{N} matrix all indicate a mapping to the j=J_{CI-2}^{th} submatrix, Mⱼ. Given that N elements of updated extrinsic information are mapped during each parallel transfer cycle to N different sub matrices, i.e., Mⱼ for j=1, 2 . . . N, there must be at least two submatrices, Mⱼ, to which no updated elements of extrinsic information are mapped during the i_{row}^{th} parallel transfer cycle. Thus to resolve this depth 3 output contention event, all that is needed to achieve a contention free parallel transfer cycle is to determine if at least two coded bits involved in the output contention event have remaining unmapped coded bits from the same respective codewords in the two submatrices, Mⱼ, to which no updated elements of extrinsic information are mapped during the i_{row}^{th} parallel transfer cycle. If so, two of the above-mentioned bit swaps are performed to thereby perform a mapping T^{(1, 2)}: CI₂⁽¹⁾→CI₂⁽²⁾, where CI₂⁽¹⁾ corresponds to the CI-2 design matrix having the above mentioned depth-3 output contention, and CI₂⁽²⁾ corresponds to a new valid CI-2 design matrix free of above mentioned depth-3 output contention. As mentioned above, any such sequence of transformations results in a valid CI₂ matrix, so the above technique is applied as many times as needed to resolve as many output contentions as possible. If there was no sequence of transformations that could eliminate all the output contentions, then the number and depths are reduced in accordance with an output-contention performance criterion selectable by the designer. Such a performance criterion can include worst case output contention event depth, number of output contentions, average number of output contention events, and/or average output contention event depth, or any combination or variation thereof used to improve the performance of the INASL 635 while executing a CTBC code SISO iteration.

Block 725 next analyzes the quality of the mapping that was evaluated and preferably corrected during block 720. Block 725 determines if the mapping result of block 720 was acceptable based on the output-contention performance criterion. If so, a “good” is recorded and control passes to block 730 that then increments the index i_{row} and moves to the next row of the CW_{N} matrix which identifies the next N elements involved in the next parallel transfer cycle. Blocks 715,720,725, and 730 are repeated until i_{row}=nK, or until a “bad” result identifies that there an unacceptable parallel transfer cycle condition was detected. When this occurs, in this preferred embodiment, control next optionally passes back to block 710 in order to modify the assignment and/or ordering of outer codewords to processors, and the blocks 715,720,725, and 730 are repeated until a good result is obtained or until it is determined that no acceptable measure of output contention events could be found with the starting CI-2 constrained interleaver design matrix.

When the entire loop processes to the point where i_{row}=nK, and all mappings 720 were deemed to be acceptable 725, a set of statistics and/or results are preferably recorded in a block 735. For example, the modified CI-2 permutation function is recorded, e.g., the updated and contention reduced CI₂ constrained interleaver design matrix is recorded along with its number of output contentions, and the depths of each output contention, etc. In a preferred embodiment an acceptable result would be free of output contentions. Other statistics can be collected, for example the block 735 can run a set of simulations to determine the CI-2 interleaver gain achieved based upon the CI-2 permutation function associated with this acceptable CI-2 constrained interleaver design matrix. In an optional block 740, a set of design criteria are evaluated. If the design criteria are all satisfied, the design algorithm 700 can terminate and output the best result that was able to meet all design constraints. If, using the additional performance criteria of block 740, no acceptable result was identified, control passes back to block 705 where a new CI-2 is designed and the process is repeated until the performance criteria of block 740 are met. If after exhausting all possibilities no solution is found, the best design is preferably selected that most closely acceptably met the performance criteria.

In accordance with the exemplary computer aided design method of FIG. 7, a software loop can be additionally placed around a CI-2 design software routine 700 to generate multiple different CI-2 permutation functions and the method repeated until an acceptable or best solution is found. Using this software loop, many alternative CI-2 permutation functions and inverse permutation function pairs can be analyzed to determine a preferred CI-2 permutation function that reduces a measure such as the total number of clock cycles needed to implement a given CI-2 permutation and inverse permutation function pair on a type of interconnection network 670, 675. It is noted that since the CI-2 inverse permutation function merely reverses the direction of the CI-2 permutation, that the above optimization of the CI-2 permutation function will automatically and implicitly optimize the inverse CI-2 permutation function in the same way. Hence it is to be understood that an alternative embodiment of the design method 700 is to perform essentially the same steps, but by stepping in column major order through the Mⱼ matrices and carrying out steps 715,720,725 and 730 to consider an output contention event to be when two or more elements from the same location in two different Mⱼ matrices map to a single row location in a corresponding destination/target row of the CW_{N} matrix.

While the design method 700 will typically find an output contention free solution, it also can identify CI-2 permutation and inverse permutation function pairs with low numbers of output contentions and minimized output contention depths. Consider an example where no output contention free CI-2 permutation was found, or that one was found, but the reordering caused another problem, such as the interleaver gain to be below a desired threshold. In such cases a CI-2 permutation is preferably selected that was identified by the method 700 that meets the interleaver gain threshold, and also has a minimal set of parameters related to the number of output contentions, the depths of the output contentions, and the way the output contentions are distributed over time and/or the processors. In such cases, the output buffers 675, 685 and all their variants discussed above can be efficiently designed to take advantage of a low complexity set of buffering requirements that were identified by block 740.

Alternatively, the method 700 can be modified in alternative embodiments where the processors 605, . . . , 650 can modify the order in which they calculate and output their extrinsic information elements. For example, consider an embodiment of the system 600 where all of the processors 605, . . . , 650 operate in a SIMD mode, i.e., they all work in parallel to update the extrinsic information in their respective I-REG and O-REG register banks, one element at a time, and in lockstep. Further, in this embodiment, the processors include as a local functional unit that includes an address sequencer state machine. With this additional processing power, the method 700 can be run to conclusion, and can more easily determine a desirable solution with a high interleaver gain and provide fully output-contention-free parallel transfer cycles for use in all SISO iterations. To see how this can be achieved, consider an example where the IRCC SISO decoder block 515 uses the log-MAP algorithm to decode its respective subsequence of IRCC encoded bits. In this example, also consider a case where the OBC SISO decoder block 525 uses the Pyndiah algorithm to decode its respective codeword(s) of the outer code B. In algorithms used to decode the IRCC in block 515, such as the MAP, Max-Log-MAP, Log-Map and SOVA (soft output Viterbi algorithm), all of these decoding algorithms require a set of state metrics to be updated before the extrinsic information can be computed. A forward recursion is carried out to update a set of alpha metrics, and a backward recursion to compute a set of beta metrics. Once the state metrics have been updated, all of the n elements of extrinsic information can be updated in any order or in parallel for that matter. Similarly, using the Pyndiah algorithm, for example, all of the final n elements of extrinsic information generated and output during a pass of OBC SISO decoding can be computed and output in any order or in parallel for that matter.

Given the above flexibility in the order in which the extrinsic information can be calculated and output from the decoders 515 and 525, the analysis of FIG. 6 can be extended to provide a modified version of the design method 700 that provides still more solutions. A key assumption made in discussing FIG. 6 and FIG. 7 above was that, at substantially the same time, all of the N processors compute and output N elements of extrinsic information that correspond to a row of the CW_{N} matrix. These N elements of extrinsic information will then be used in a parallel transfer cycle on the parallel VLSI system 600. Like the previous example and discussion of FIGS. 6 and 7, suppose that each processor 605, . . . , 650 responds to a single instruction stream, i.e., the processors 605, . . . 650 operate in a SIMD mode. This time, though, by way of example, assume that each processor has a 2-bit address generator state machine that computes a sequence of 2-bit addresses. This sequence of 2-bit addresses is periodically generated once every complete CTBC code SISO iteration, 515, 525. Also assume that there is a register indirect addressing mode with auto increment (or its equivalent broken into one or more instruction cycles). That is, when the register indirect addressing mode is used to address an element in a memory denoted “Mem”, and if the register in the register direct addressing mode is R, then the register indirect addressing mode with auto increment will access the memory location Mem[R++]. In this notation, R++ tells the processor to use the current value of R as a pointer into the memory, Mem, and then update the pointer register as R=R+1. In essence, this is the addressing mode used by the processors to step through the rows of the CW_{N} matrix in the discussions relating to FIG. 6 and FIG. 7 above. Note that the pointer register R is also called an “address register” in the processor arts and also note that the above-mentioned “memory” can be any of the I-REG register bank, O-REG register bank, or the LM (local memory) associated with any given processor. In terms of the CW_{N} matrix, the register R can be viewed as a row pointer register that generates the sequence, i_{row}=1, 2, . . . , nK.

In the current embodiment under discussion where each processor is equipped with a respective local 2-bit address generator state machine, next define a register indirect addressing mode with a +4 auto increment (or its equivalent broken into one or more instruction cycles). That is, when the register indirect addressing mode is used to address an element in a memory denoted “Mem”, using the address register R, then the register indirect addressing mode with +4 auto increment will access the memory location Mem[R++(4)2b]. In this notation, Mem[R++(4)(2)] tells the processor to use the current value of R as a pointer into the memory, Mem, but with the 2 LSBs of R replaced by the current value of the 2-bit address generated by the local address generator state machine. The Mem[R++(4)(2)] addressing mode next updates the pointer register as R=R+4 and then updates the 2 LSBs in accordance with the next state of the local address generator state machine. Now if R is again considered to be a row pointer into the CW_{N} matrix, then the values of R step through the sequence, i_{row}=1, 2, . . . , nK, but in a modified order where each set of four rows can be swapped in any permuted order individually on every column, j.

By considering the N parallel sequences of 2-bit addresses as a design parameter, the Mem[R++(4)2b] addressing mode provides the method 700 with a new degree of freedom and increases the ability to find good solutions. This can be used in an alternative embodiment of the method 700 where the blocks 715, 720, and 725 can work with four rows at a time, whereby the ordering of each of the N different 2-bit address subsequences can be adjusted to avoid irresolvable output conflicts that would occur if the method 700 were only allowed to optimize the parallel transfer cycles one row at a time as discussed above. With the above-defined addressing mode (or its equivalent), given by Mem[R++(4)2b], in any parallel transfer cycle, each of the N processors can select to compute and output an element of extrinsic information selected from one of four adjacent rows to be used in a subset of four parallel transfer cycles. That is, the blocks 715, 720 and 725 can now work with four rows at a time in order to find four parallel transfer cycles containing N elements each, from the 4N possible elements in the four rows of the CW_{N} matrix as pointed to by the most significant bits of the row address pointer, R (R less the 2 LSBs that select a specific row in a set of four rows). The addition of the simple 2-bit address generator state machines on each processor increases the flexibility to find a sequence of nK output-contention-free parallel transfer cycles, using this alternative embodiment of the method 700, where the N elements involved in any given parallel transfer cycle can be selected from one of four adjacent rows.

In general, the above type of embodiment can be generalized according to Mem[R++(2^{x})xb] where in this notation, Mem[R++(2^{x})xb] is an addressing mode (or equivalent set of instructions) that tells the j^{th} processor to use the current value of R as a pointer into the memory, Mem, where the x LSBs of R are replaced by the value of a current set of x bits generated by a local address generator. state machine. Next, the Mem[R++(2^{x})xb] addressing mode tells the j^{th} processor and to then update the pointer register as R=R+2^{x} and to then automatically let the local state machine update the x LSBs in accordance with the next state of the local address generator state machine. The larger x is, the more flexibility in finding a sequence of nK output-contention-free parallel transfer cycles, where the N elements involved in any given parallel transfer cycle can be selected from one of 2^{x} rows. The smaller x is, the simpler the state machine at each processor. Therefore, the computer aided design software method 700 can be further modified by performing the method 700 for different values of x=0, 1, 2, . . . until a sequence of nK output-contention-free parallel transfer cycles is found (or until any other suitable output-contention performance criterion is satisfied). Once the lowest value of x is found that meets the design objective, the processors can be optionally designed to be as simple as possible by using this determined lowest value of x.

Recall that the design philosophy discussed in connection with FIG. 3 through FIG. 7 was to ensure that the system 600 was designed so that the processors 605, . . . 650 could continuously alternate between computing the IRCC SISO decoding 515 and OBC SISO decoding 525 without having to wait for data, because the INASL 635 was designed and controlled/sequenced to ensure that all the updated extrinsic information would have been deinterleaved and transferred to its target location in a respective target O-REG register bank by the time the processors were ready to alternate between IRCC SISO decoding and OBC SISO decoding. Similarly, the INASL 635 was designed and controlled/sequenced to ensure that all the updated extrinsic information would have been interleaved and transferred to its target location in a respective target I-REG register bank by the time the processors were ready to alternate between OBC SISO decoding and IRCC SISO decoding. As discussed in FIG. 3 to FIG. 7, various embodiments of the INASL can be designed to completely eliminate or to significantly reduce the need for the processors 605, . . . , 650 to lose cycles due to waiting for updated extrinsic information. That is, the discussion of provided above in connection with FIG. 3 through FIG. 7 is provided to show ways that the INASL 635 may be designed and sequenced to keep the processors 605, . . . , 650 busy 100% or nearly 100% of the time.

Although the above discussion of the method 700 of FIG. 7 concentrates on reducing output contentions, alternative embodiments of the method 700 can be used to help design and program the interconnection network 670, 680. As discussed above, the interconnection networks 670, 680 can optionally be implemented as multistage interconnection networks. Such multistage interconnection networks include hypercube networks, shuffle-exchange networks, Banyan networks, Delta networks, Omega networks, mesh of tree networks, and other interconnection network topologies known to those of skill in the art of parallel processing architectures. It is known that some multistage interconnection networks can implement all possible N-to-N permutations, but in so doing, internal contentions may arise at internal resources such as switching elements or inter-stage input or output ports or registers. It is also known that other types of multistage interconnection networks can only implement, for example N! (N factorial) number of permutations. While such interconnection networks have reduced performance relative to a perfect N-to-N crossbar switching fabric, such interconnection networks can be much more area efficient in terms of the VLSI area and power consumption needed to implement the interconnection network. Hence the present invention contemplates, as an alternative embodiment of the method 700, that the blocks 725, 735, and/or 740 can be programmed to analyze internal conflicts and/or the effects of other limitations such as a limited permutation capability (e.g., an interconnection network that can only implement N! permutations). In this type of embodiment, a target interconnection network is assumed and the blocks 725, 735, and/or 740 then seek to optimize the performance of parallel transfer cycles as discussed above, but specifically operating on the target interconnection network. An outer loop may be placed around this type of embodiment of the method 700 to cycle through different choices of the type of target interconnection network to be used. With this optional outer loop (not shown) the method 700 could use blocks 725, 735, and/or 740 to select a best practical implementation by reducing or minimizing a measure that takes into account the overall parallel transfer cycle performance as described above, but weighted against the VLSI area and/or power consumption complexity of the implementation of the interconnection network 670, 680 that are evaluated by the design loop 700 or its equivalents and variants. In some cases a worst case area requirement may be applied to eliminate certain possibilities, such as a full blown cross bar switching fabric.

Referring now to FIG. 8, consider an alternative system 800 that is closely related to the system 600. To reduce repetitiveness, everything said about the system 600 applies to the system 800, except for the difference described below. As previously discussed, the processors 605, . . . 650 can be designed in a variety of ways. The system 800, allocates hardware resources such as functional units, data paths, memory and program instruction streams that pertain to IRCC SISO decoding in a set of IRCC processors 606, . . . , 656, which have associated therewith respective local memories 611, . . . , 656, and I-REG register banks 616, . . . , 668. The IRCC processors carry out IRCC decoding according to algorithms like the MAP, log-MAP, MAX-log-MAP, SOVA and the like as discussed above to perform the IRCC SISO decoding of CTBC code SISO decoding 500. The design philosophy behind the system 800 is similar to the system 600. In the system 800, the INASL 635 will use its instruction counter sequencer 695 to sequence through the interleaving 535 and deinterleaving operations 510, 520 in order to keep the processors 605, . . . , 650 busy performing OBC SISO decoding operations as close to 100% of the time as possible. However, the additional IRCC processors 606, . . . , 651 are additionally provided to increase throughput and to further reduce CTBC code SISO iterative decoding latency.

It should be understood that the exact local bussing and configuration topologies of the processor and resource sets (606,616,611), . . . ,(651,668,656) are exemplary and are provided to illustrate the key concepts of the present invention, but many variations are envisioned and possible. For example, an adder could be placed in the data path between the registers 630, . . . 645 and the I-REG register banks 616, . . . , 668 in order to add to each OBC SISO decoding updated element of extrinsic information a corresponding element of the input metric vector, rₛ, so that the I-REG register banks 616, . . . , 668 could hold gamma values instead of updated elements of extrinsic information (gamma values are well known to those of skill in the art as is evident by reviewing P. Robertson et al. reference as cited above). In an alternative embodiment, the processors 605, . . . , 650 can perform this same addition before and thus send the gamma values instead of the updated extrinsic information through the INASL to its destination I-REG register bank, in this case, 616, . . . , 668. By allowing the processors 605, . . . , 650 to compute the gamma values used in IRCC SISO decoding, the input metric vector, rₛ, need only be stored once, in local memories 610, . . . , 665. However, the gamma calculation can occur in either the processors 605, . . . , 650, or the processors 606, . . . , 651, depending on the embodiment.

As discussed in connection with the system 600, each of the processors 605, . . . , 650 can be implemented as a dual core processor, where at different times, both cores could be performing OBC SISO decoding on different codewords. At other times, both cores could be performing different computations such as the different subsequences of gamma value updating and forward and backward state metric recursions of the log-MAP algorithm, and both cores could then compute different subsequences of extrinsic information. At other times, one core could be still working in the IRCC SISO decoding operations while the other is performing OBC SISO decoding on a codeword of the outer code B that has already propagated through the INASL 650. In the system 800, instead of using a dual core approach in the processors 605, . . . , 650, a pipelining form of parallelism is achieved by effectively moving the second core 606, . . . , 651, to the other side of the INASL 635. In the system 800 the processors 605, . . . , 650 preferably perform OBC SISO decoding 525, while the processors 606, . . . , 651, perform IRCC SISO decoding in pipeline-parallel with OBC SISO decoding. By the time the processors 605, . . . , 650 have transmitted their final updated elements of extrinsic information (or updated gamma values) through the INASL 635, if the sequencing of the INASL is performed in accordance with an aspect of the present invention as discussed in further detail below, the processors 605, . . . , 650 can almost immediately begin computing their next set of OBC SISO decoding computations, staying busy close to 100% of the time, and further reducing latency by allowing the IRCC SISO decoding 515 to be computed in parallel with the OBC SISO decoding 525. While the OBC SISO decoding and the IRCC SISO decoding cannot be performed in parallel per se, in accordance with an aspect of the present invention, using the system 800, the IRCC SISO decoding operations and the OBC SISO decoding operations can be performed in pipelined manner, which allows a form of lower level parallelism to be exploited. Using this pipelined form of parallelism, OBC SISO decoding of a current iteration of CTBC code SISO iterative decoding and a subsequent IRCC SISO decoding of a subsequent iteration of CTBC code SISO iterative decoding can be performed in parallel, via the use of special program sequencing and via the use of pipelining of operations, as discussed below.

It is important to realize that OBC SISO decoding 525 requires roughly ten times as much computation (decoding complexity) as is required by the IRCC SISO decoding 515. Therefore, an aspect of the present invention is to design the processors 605, . . . , 650 to be more powerful than the IRCC processors 606, . . . 651. Viewed another way, the IRCC processors 606, . . . 651 are preferably designed to be as simple as possible. Since the IRCC processors only need to compute pass of IRCC decoding in the time it takes the processors 605, . . . , 650 to carry out one pass of OBC SISO decoding, the IRCC processors 606, . . . 651 could be designed to be roughly ten times simpler in terms of hardware resources as compared to the processors 605, . . . , 650 in some embodiments. The processors 606, . . . , 651 are preferably implemented as SIMD processors, and their operation can be controlled by an IRCC SISO decoding instruction stream that may be stored as a field in the VLIW memory 690 (or its equivalent) or can be stored in a separate SIMD instruction memory, depending on the embodiment.

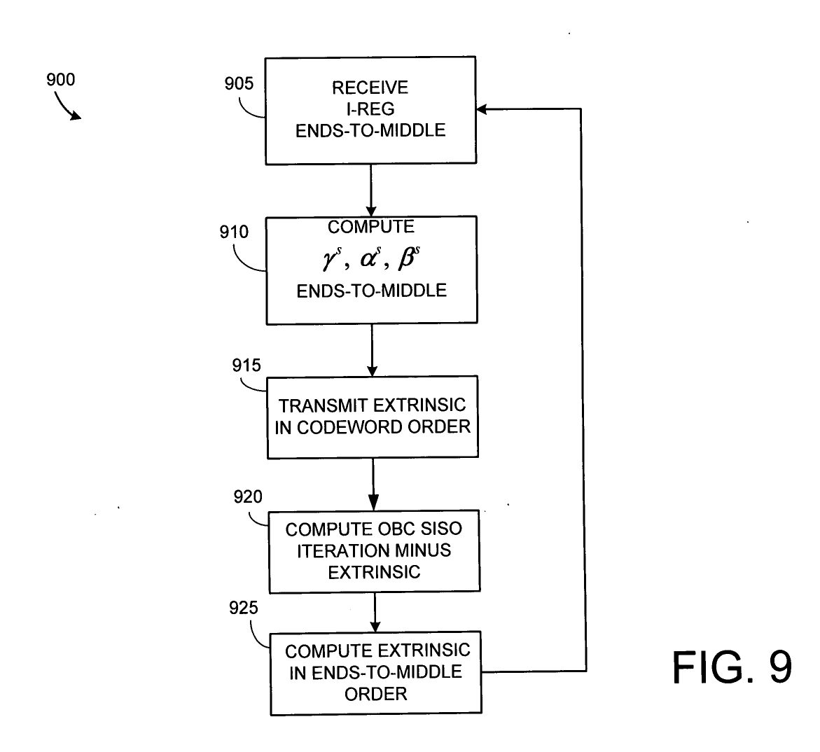

Another preferable variation that can be made in some embodiments of the system 600 is to recognize that M<N IRCC processors 606, . . . 651 could be deployed. That is, in some alternative embodiments, the number of elements of extrinsic information updated during IRCC SISO decoding on each of the M<N IRCC processors 606, . . . 651 need not be the same as the number of elements of extrinsic information updated during OBC SISO decoding on each of the processors 605, . . . , 650. Hence in FIG. 8, some embodiments replace the N in blocks 651, 668, and 656 with M, where M≠N and typically in such embodiments, M<N. That is, the present invention contemplates that fewer IRCC processors 606, . . . 651 need be used as compared to the number of processors used to perform OBC SISO decoding, since IRCC SISO decoding requires much less work than OBC SISO decoding. While the specific examples discussed herein focus on an example where N IRCC processors 606, . . . , 651 are deployed, it is to be understood that the discussion above and below related to FIGS. 8 and 9 could be readily adapted to the alternative and often preferable embodiments that deploy M<N of the IRCC processors 606, . . . , 651. Such alternative embodiments also reduce the number of data paths and circuit area consumed by the switching fabric of the INASL 635 because only M<N of the ports 630, . . . , 645 are needed. The number of IRCC processors 606, . . . , 651 used is a design choice where silicon area is traded for a decrease in throughput and an increase in latency relative to the case where N IRCC processors are deployed.

In order to understand the operation of the system 800, consider the specific OTN-based example above to decode the same CTBC code, where K=8 codewords of the outer code B are computed on each one of the processors 605, . . . , 650 per SISO iteration 525, but this time where the CTBC code SISO iterations are carried out on the system 800. In this example, the number of processors, N, in FIG. 8 is thus N=ρL/K=239*8/8=239. Also, in this example, M=N number of IRCC processors 606, . . . , 651 are deployed. Therefore, in this example, each of the I-REG register banks 616, . . . , 668 and each of the O-REG banks 620, . . . , 660 will need to hold K*n=8*72=576 elements of extrinsic information (or optionally gamma information in the I-REG banks as discussed above and as is possible in alternative embodiments of the system 600 as well).

To see how pipelining is applied, refer to FIG. 8 and also to FIG. 9 where a method 900 is depicted in flow chart form. To illustrate the concepts, without loss of generality, the example of the previous paragraph is assumed throughout the subsequent discussion of the method 900. Start by considering the continuous cyclic set of decoding computations performed on the system 800 as it continuously and periodically performs CTBC code SISO decoding 500 on successive frames of CTBC coded information. Since the operation is cyclic, without loss of generality, let us start the discussion while each of the processors 605, . . . , 650 are performing OBC SISO decoding. For example, this decoding may be performed in accordance with the Pyndiah, reduced-complexity Pyndiah, OSD, or other similar block code or LDPC based SISO decoding algorithm designed for decoding the outer code B. In this particular example, assume the Pyndiah algorithm is being used. At this point in the cyclic operation of the CTBC code SISO decoding 500, assume the O-REG register banks 620, . . . , 660 have already received all the extrinsic information needed to perform a current pass of OBC SISO decoding. This corresponds to an action 920 as indicated by FIG. 9. In the block 920, each of the processors 605, . . . , 650 can perform all the steps of Pyndiah decoding for one or more of K=8 codewords of the outer code, B, per processor, minus the last step of the Pyndiah SISO decoding iteration, which corresponds to the calculation and transmission of the updated extrinsic information. Once all the steps of Pyndiah decoding for all of the K=8 codewords of the outer code, B, have been performed, minus the last step of computing the updated extrinsic information values, then at this point in the example, each of the processors 605, . . . , 650 will have computed everything they need to begin to compute and transmit the updated extrinsic information (or corresponding gamma information) for all K=8 codewords of the outer code, B per processor. Viewed another way, each processor, Pⱼ for j=1, . . . , N, can compute and output to the INASL 635 (via optional registers 625, . . . , 640) any of the K*n=8*72=576 elements of OBC SISO decoding updated extrinsic information in any desired output ordering.

In this example, each processor 605, . . . 650 is preferably equipped with an addressing mode that corresponds to Mem[R++(2^{x})xb] as discussed above. In this specific example, the register R is selected to be 10 bits wide and the number of LSBs to be generated by the local address generator is x=10. This selection allows the 2¹⁰=1024>576 elements to be accessed in any j^{th} respective ordering that will be programmed individually to be implemented by a respective address generation state machine preferably located at a respective processor, Pⱼ, of the processors 605, . . . 650.

The order in which the extrinsic information updated and output during the OBC SISO decoding is determined as follows. Consider the N O-REG register banks 620, . . . , 660, which each contain 576 elements of extrinsic information ready to be updated in any order. In this example, the 576 elements of extrinsic information correspond to K=8 number of 72-bit codewords of the outer code, B. Next consider the j^{th} I-REG register bank that will be needing to first compute gamma values by simply adding an input metric to the updated OBC SISO decoding updated element of extrinsic information element. As mentioned previously, the gamma computation is a simple addition and the respective processor containing any updated extrinsic information element to be inserted into the j^{th} I-REG register bank can alternatively compute and pass a gamma value through the INASL instead of an element of OBC SISO decoding updated extrinsic information. This may be desirable in order to only need to store the rₛ vector in the local memories 610, . . . , 655, instead of also needing to store received signal metrics in the local memories 611, . . . , 656 in the system 800. If the gammas are computed on the processors 606, . . . , 651, then a copy of the rₛ vector will need to be stored, for example in the local memories 611, . . . , 656. Hence it is recognized the gammas can be calculated in either of the processors 606, . . . , 651 or the processors 605, . . . 650, depending on the embodiment.

At this point in the processing, 920, the gamma values can be computed in any order, so the calculation of gamma does not affect the selection of the ordering. Instead, as is well known to those of skill in the art (e.g., see Robertson reference cited above) right after the gammas are updated, the IRCC SISO decoding will need to run a forward recursion to update a set of alpha state metrics, and the IRCC SISO decoding will also need to run a backward recursion to update a set of beta state metrics for each j^{th} IRCC parallel subsequence. Both the forward and backward recursions can be computed at the same time, if a proper ordering is provided. Think of the j^{th} I-REG register bank as being arranged horizontally. Then the forward alpha recursions run from left to right, and the backward beta recursions run from right to left.

Therefore, at 925, the processors 605, . . . , 650 preferably work together to compute and send out via the INASL 635 the updated extrinsic information (or the gamma information depending on the embodiment) in the order to fill the I-REG banks 616, . . . , 668, in an order from the outer ends to the middle (an “ends-to-middle” ordering). To provide a specific example, consider the case where M=N number of IRCC processors 617, . . . 667 are deployed. In this example, each I-REG holds 576 elements of data, the ends-to-middle ordering is defined as alternating between 1+i, and 576−i for i=0, . . . , 287, noting that 287=288−1 and 288=576/2. It should be noted that the updated extrinsic information coming into the j^{th} I-REG register bank in ends-to-middle order will be sequencing in from in from all N processors 605, . . . , 650 via the INASL 635 in successive parallel transfer cycles. Computer aided design software is preferably used at design time using a variation of the design method shown in FIG. 7 to efficiently implement these parallel transfer cycles. In this type of design-of-sequencing embodiment, the above-mentioned metadata is used to determine which elements of any given O-REG bank correspond to the minimum I-REG register bank index (left-most I-REG register bank element) and/or maximum I-REG register bank index (left-most I-REG register bank element). Collectively, the processors 605, . . . , 650 are sequenced to cause the I-REG register banks 616, . . . , 668 to fill up in the ends-to-middle order discussed above. In a some embodiments of the present invention each j^{th} respective one of the RCC-processors 606, . . . , 651 can implement the functionality of the Mem[R++(2^{x})xb] addressing mode as discussed above, where again the register R is selected to be 10 bits wide and the number of LSBs to be generated by the local address generator is x=10.

At 905, the j^{th} I-REG register bank receives from the INASL 635 the sequence of updated extrinsic information in the above-described ends-to-middle order. This ordering will fill in the j^{th} respective I-REG bank in an ordering that allows the forward and backward recursions to begin executing in both directions as the I-REG bank is being filled. The computations of 910 are preferably performed in an overlapped manner with the reception of the ends-to-middle ordered updated extrinsic information (or gamma values in some embodiments as discussed above). Once the I-REG bank is filled, the forward and backward recursions will each be half way done and all the updated gamma values will be in place to compute the rest of the forward and backward recursions.

At this point in the process, at block 910, the forward and backward recursions are preferably allowed to proceed to completion. Once these recursions complete, all of the alphas and betas state metrics will have been computed. At this point, at block 915, the output elements of the IRCC SISO decoding can be computed and/or output in any order. For example, if the log-MAP SISO decoding algorithm is being used by the RCC-processors 606, . . . , 651, what is left to be computed is one or more a find-the-maximum operations, a correction term calculation, and an addition. In some embodiments, because the IRCC SISO decoding is fast as compared to the OBC SISO decoding, the IRCC SISO decoding output extrinsic information can also be computed after each alpha and beta value are computed in the ends-to-middle ordering as the j^{th} respective I-REG register bank is filling up from the ends to the middle in block 910, pipelined with the execution of block 905.

At block 915 it is assumed that some or all of the alpha and beta values have been computed. In some embodiments all of the alpha and beta values are available before the step 915 begins. At step 915, each respective one of the IRCC processors 606, . . . , 651 will execute instructions to cause the IRCC processors 606, . . . , 651 to work together to each compute a respective designated first codeword first. Preferably the IRCC processors 606, . . . , 651 will be programmed to next compute and send updated extrinsic information for second designated codeword second and so on until all K codewords worth of updated extrinsic information are received at the O-REG register banks 620, . . . , 660 in this codeword order. This is done to allow all the processors 605, . . . , 650 to begin decoding their first respective first codeword immediately instead of having to wait for the entire set of IRCC SISO decoding operations to complete. This allows blocks 915 and 920 to perform pipeline-parallel processing. In this example where K=8 codewords are decoded per processor, the processors 605, . . . , 650 complete all the decoding operations of block 920 for a first respective codeword minus the calculation of the updated extrinsic information. Using the ordering of 915, all of the second respective codewords will be in position and for OBC SISO decoding on all of the processors 605, . . . 650 before the time the first codeword is finished being partially decoded as discussed above. This is because OBC SISO decoding takes roughly ten times as much coding complexity as IRCC SISO decoding. All of the other codewords of updated extrinsic information from the IRCC SISO decoding will also be in place in the O-REG banks before they are needed. Hence with the system 800 and using the orderings as discussed in connection with FIG. 8 and FIG. 9, the processors 605, . . . , 650 will be kept busy all the time minus a small wait while the IRCC processors 606, . . . , 651 compute the a middle portion of each pass through IRCC SISO decoding that corresponds to the time it takes to compute half of the alpha recursion, half of the beta recursion, and the time it takes to compute and output the IRCC SISO decoding updated extrinsic information for the first codeword. In examples where M<N, IRCC processors 617, . . . , 667 are deployed, the waiting time will generally increase, but the complexity of the INASL 635 will to decrease. Traffic optimizations using the matrices of FIG. 6 and a modified version of FIG. 7 would attempt to get a first codeword for each of the N processors 605, . . . , 650 as close as possible to the outer ends of the IRCC parallel subsequences to minimize this waiting time.

The above ordering is determined at design time using the above mentioned metadata discussed in connection with FIG. 6 and FIG. 7. The computer aided design software looks at the coded bits in each of the I-REG register banks 616, . . . , 651 and uses the metadata to determine all of the coded bits that correspond to any and all of the first N respective codewords to be decoded by the processors 605, . . . , 650. The computer aided design software then preferably generates the orderings of extrinsic information updating and outputting from the M<N I-REG register banks 616, . . . , 668 in an ordering that gets the first respective codewords to be decoded to their respective processors 605, . . . , 650 first. The extrinsic information corresponding to coded bits of the any and all codewords from the second set of codewords to be decoded by the processors 605, . . . , 650 are preferably sent second, and so on. At the same time, aspects of the method of FIG. 7 may be used to make efficient use of the INASL 635 by reducing internal and output contentions and the like.

The above example shows that much of the work associated with IRCC SISO decoding can be done in pipeline-parallel with OBC SISO decoding. The general concept is to first compute the portions of OBC SISO decoding that have a sequential dependency and cannot be computed in any arbitrary order. Once the portions of OBC SISO decoding that cannot be computed in parallel are computed, the extrinsic information related to OBC SISO decoding can be updated and transmitted in any order. The updated extrinsic information from the OBC SISO decoding is then calculated in the ends-to-middle ordering on the processors 605, . . . 650 and is sent to a sequence of target I-REG register banks to collectively cause all of the I-REG register banks to fill up. This allows half or more of the computations associated with IRCC SISO decoding that have a sequential dependency to be computed while the processors 605, . . . , 650 are actively busy. Thus the IRCC SISO decoding operations are overlapped and pipelined with OBC SISO decoding operations associated with a previous CTBC code SISO decoding iteration. Once the alpha and beta recursions of the IRCC SISO decoding are complete, the IRCC SISO decoding updated extrinsic elements are calculated and transmitted in an ordering that allows a first codeword to begin being decoded on the processors 605, . . . , 650 in a subsequent pass through OBC SISO decoding. From here forward, the next pass through OBC SISO decoding can go to completion without having to wait any more for the IRCC SISO decoding iteration to finish. This is because the IRCC SISO decoding completes much faster than the OBC SISO decoding. Hence using the approach of FIG. 8 and FIG. 9, instead of having to effectively wait for the complete pass through IRCC SISO decoding to execute before beginning the SISO iteration, the effective waiting time on the system 800 will be reduced to the time it takes to compute half of the alpha values, half of the beta values, and one codeword worth of IRCC SISO updated output elements of extrinsic information. That is, the system 800 using the method 900 can reduce latency and increase throughput by this amount as compared to the system 600. The price is more hardware resources are needed and the percentage of time the processors are kept busy is less than the system 600 which is nearly 100%.

As discussed above in connection with FIG. 8, 1≦M<N IRCC processors 606, . . . , 651 can optionally be deployed. This reduces the VLSI area that needs to be devoted to the IRCC processors 606, . . . , 651 and reduces the VLSI area that needs to be deployed in the INASL 635 as well due to the reduced number of ports 630, . . . , 645. That is, in such embodiments, as per FIG. 4, the N-to-N interconnection network 670 reduces to an M-to-N interconnection network 670 and the N-to-N interconnection network 680 reduces to an N-to-M interconnection network 680. Also, the output buffer 685 can be implemented with M<N channels, thereby reducing its VLSI area footprint. In such embodiments, where M<N IRCC processors 606, . . . , 651 are deployed, an embodiment of the method 700 is preferably used to arrange the codewords in the CW_{N} and to apply transforms to the CI₂ matrix in such a way that the IRCC processors 606, . . . , 651 and the instruction counter sequencer 695 are sequenced to cause N first codewords to be delivered to the N different O-REG banks 620, . . . , 660 as soon as possible. As soon as the first codeword worth of IRCC SISO decoding output data is delivered to the processors 605, . . . , 650, the processors 605, . . . , 650 can once again be actively engaged. Hence the same concepts as described above for the case where M=N different IRCC processors 606, . . . , 651 are deployed can be applied to embodiments where M<N and thus there are different numbers of elements of extrinsic information updated by the IRCC processors 606, . . . , 651 and the processors 605, . . . , 650.

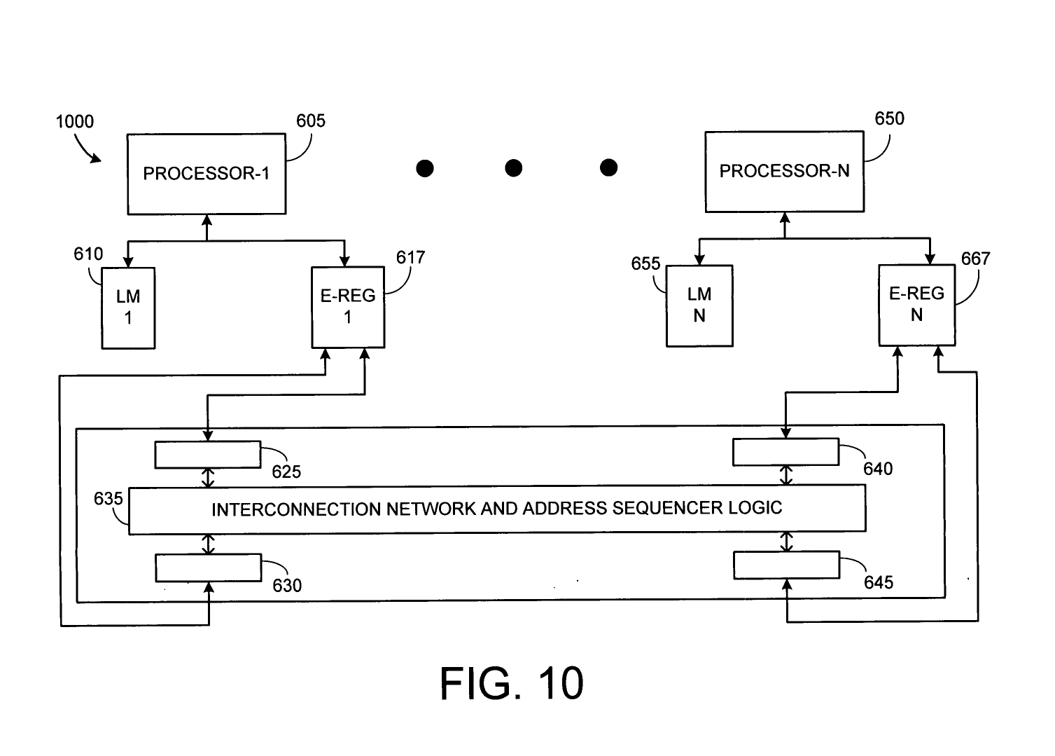

Referring now to FIG. 10, consider an alternative system 1000 that is closely related to the system 600. Nearly everything stated above describing the system 600 applies to the system 1000, so only the differences will be highlighted here. Note that the I-REG register banks 615, . . . , 665 and the O-REG register banks 620, . . . , 660 of the system 600 are replaced by the E-REG register banks 617, . . . , 667 in the system 1000. Also note the difference between the way the I-REG and O-REG register banks are coupled to the INASL 635 via their respective optional buffer registers 625,630,640, and 645 in the system 600, in contrast to the way the E-REG banks 617, . . . , 667 are coupled to the INASL 635 via their respective optional buffer registers 625,630,640, and 645 in the system 1000. The main objective of the system 1000 is to reduce the memory/area requirements associated by the I-REG and O-REG register banks, by replacing them with a single E-REG register bank that performs the function of both the I-REG and O-REG register banks, but using half or roughly half as many memory locations. That is, the system 1000 provides a potential savings in VLSI area resources as compared to the system 600. In a preferred embodiment, the E-REG register banks 617, . . . , 667 of the system 1000 are the same size as each of the corresponding I-REG register banks 615, . . . , 665 and the O-REG register banks 620, . . . , 660 of the system 600. The term E-REG is selected to call out the fact that Extrinsic information is the main item held in the E-REG register banks (although other additional registers can be added for holding other data if desired, and gamma data can alternatively be stored in the E-REG register banks as needed for IRCC SISO decoding.)

Referring back to the matrices and vectors shown in FIG. 6, note that during IRCC decoding, the j^{th} processor, Pⱼ, performs a pass through IRCC SISO decoding of a subsequence of updated extrinsic information defined by the submatrix, Mⱼ read in column-major order. As shown in FIG. 6, and as discussed above, MⱼεB^{L×ρn/N}, for j=1, . . . , N. Because N=ρL/K, each MⱼεB^{L×nK/L}, and thus the updated extrinsic information defined by the submatrix, Mⱼ read in column-major order, includes nK elements. Note also from FIG. 6 that each of the vectors C_{w}VⱼεB^{Kn} for j=1, . . . , N, so that each j^{th} column vector C_{w}Vⱼ also has nK elements. Therefore, in the system 600, the I-REG register banks 615, . . . , 665 and the O-REG register banks 620, . . . , 660 both preferably contain nK registers to hold the updated extrinsic information generated during OBC SISO decoding and the updated extrinsic information generated during IRCC SISO decoding respectively. In the system 1000 each of the E-REG banks 617, . . . , 667 are designed to hold both the updated extrinsic information generated during OBC SISO decoding and the updated extrinsic information generated during IRCC SISO decoding. That is, the number of registers needed to hold extrinsic information in the system 1000 is half of the number of registers needed to hold extrinsic information in the system 600.

Also, as discussed in several alternative embodiments discussed above, in the system 1000, the processors 605, . . . , 650 preferably include an enhanced functional unit for specialized address sequence generation. For example in the example given above where the address generator was designed to preferably generate sequences of x LSBs, where x was preferably kept as small as possible, in the system 1000, the value of x is preferably set large enough to generate any index (memory address/register address) into the entire E-REG register bank. For example, again consider the OTN application discussed above, where ρ=239, L=8, n=72, and where K=8 codewords are decoded on each processor. In this example there are N=ρL/K=239 processors, and thus each of the E-REG register banks 617, . . . , 667 needs to hold nK=72*8=576 elements. Since there are N=ρ=239 E-REG register banks in total, the total memory requirement to hold the extrinsic in the E-REG register banks is NnK=8*72*8=36, 864 memory locations. This is half of what is used by the I-REG and O-REG register banks in the system 600. Therefore, each processor Pⱼ will preferably be provided with state machine functional unit to generate sequences of 10-bit addresses since x=10 is the smallest x that satisfies 576<2^{x}=2¹⁰=1024. Some of the extra 1024−576=448 addresses that can also be generated can optionally be populated with memory locations (registers) and used for auxiliary information (such as information passed between neighboring processors, metrics related information, temporary storage, and the like.)

In operation, the system 1000 periodically executes CTBC code SISO iterative decoding iterations 500 on successively received blocks of ρnL-element blocks of received signal metrics related to each independent block of CTBC coded information. The operation of the system 1000 is similar to or the same as any of the above mentioned embodiments of the system 600 with the exception of the addressing sequences used by the processors 605, . . . , 650 to access elements in the E-REG register banks 617, . . . , 667. Also, the specific ordering and/or buffering of the data transfer operations of the INASL 635 as depicted in FIG. 4, FIG. 5 differs between the system 600 and the system 1000.

A key concept of the system 1000 is to allow the computer aided design software method 700 to be modified to use the metadata as described in connection with FIG. 6 to determine sets of parallel transfer cycles that allow particular subset of E-REG storage locations to both transmit and receive during one or more designated parallel transfer cycles. For example, suppose that as a result of OBC SISO decoding, that processor Pⱼ transmits, during a parallel transfer cycle, updated extrinsic information from row i_{row}^{(j)}. That is, the updated extrinsic information transmitted by processor Pⱼ during this parallel transfer cycle has indices (i_{row}^{(j)}, j) in the CW_{N} matrix in FIG. 6. The metadata associated with this element of the CW_{N} matrix indicates that it will be mapped to the CI₂ matrix according to a metadata mapping relationship defined by Φ_{CI-2}:CW_{N}(i_{row}^{(j)},j)→M_{jφ}(i_{CI2},j_{CI2}), where (i_{CI2},j_{CI2}) are indices into the respective submatrix partition M_{jφ}, where the associated element CW_{N}(i_{row}^{(j)},j) maps into submatrix partition, M_{jφ}, by virtue of the CI-2 permutation function as defined by the CI₂ constrained interleaver design matrix. Given that the CI₂ matrix has L rows, and given that each j^{th} one of the E-REG register banks 617, . . . , 667 hold, at the beginning of OBC SISO decoding 525, a column C_{w}Vⱼ of the CW_{N} matrix, and later, at the beginning of IRCC SISO decoding, a submatrix Mⱼ, preferably stored in column-major order. Therefore one can define a second metadata relation as Φ_{CW-N}:Mⱼ(i_{CI2},j_{CI2})→CW_{N}*(L*i_{CI2}+j_{CI2},j). Chaining these metadata relations provides Φ_{CI-2}Φ_{CW-N}:CW_{N}(i_{row}^{(j)},j)→CW_{N}(L*i_{CI2}+j_{CI2},j_{φ}) [symbol] CW_{N}(i_{row}^{(j2)},j₂). This concept can next be propagated as Φ_{CI-2}Φ_{CW-N}:CW_{N}(i_{row}^{(j2)},j₂)→CW_{N}(i_{row}^{(j3)},j₃), and so on, for example, until CW_{N}(i_{row}^{(jN)}, j_{N}) is reached.

The above metadata relations can be viewed as linked lists of metadata that allow the computer aided design software 700 or a variant thereof to determine a chain of updated elements of extrinsic information produced during OBC SISO decoding that would be overwritten in the E-REG banks 617, . . . , 667 if the CW_{N}(i_{row}^{(j)}, j) element were to be transmitted in a parallel transfer cycle. Since each element in the CW_{N} matrix is only transferred once from any particular pass through OBC SISO decoding for subsequent use in IRCC SISO decoding, it is known ahead of time that if this entire linked list of updated elements of extrinsic information produced during OBC SISO decoding were to be sent in a parallel transfer cycle via the optional registers 625, . . . , 640, that all of the elements received on the at the optional registers 630, . . . , 645 would need to be written into the same locations from which the linked list of data elements were transmitted. A subsequent parallel transfer cycle can start by initializing the linked list according to Φ_{CI-2}Φ_{CW-N}:CW_{N}(i_{row}^{(jN)},j_{N})→CW_{N}(i_{row}^{(j)},j), where this new CW_{N}(i_{row}^{(j)}, j) is different from the one used as the starting point of the previous linked list. That is, the notation CW_{N}(i_{row}^{(j)}, j) denotes a seed-starting element for each parallel transfer cycle's linked list. Each parallel transfer cycle's linked list defines the set of data elements that will be transferred during a given parallel transfer cycle. This way, different sets of linked lists can be generated until the process has been performed nK times. That is, instead of stepping through the CW_{N} matrix by taking groups of N elements on the row indexed by i_{row} for i_{row}=1, . . . , nK, the elements of updated extrinsic information sent each parallel transfer cycle are determined in accordance with the above sequence of linked lists of N elements each.

To understand how this can be performed, consider an alternative embodiment of FIG. 9. In this alternative embodiment, the OBC SISO decoding is carried out in accordance with block 920 as discussed above in connection with FIG. 8. Once the step 920 is carried out, all of the elements of OBC SISO decoding extrinsic information can be computed and/or output in any desired order. Hence following block 920, control passes to block 925, but the ordering of block 925 uses the ordering defined by the above sequence of nK linked lists of meta data instead of the ends-to-middle ordering of the previous embodiment of block 925. That is, the ends-to-middle ordering is replaced by the ordering defined by the sequence of nK linked lists as discussed immediately above. Block 905 is also modified to receive each parallel transfer cycle whose elements are determined in accordance with the above described sequence of nK linked lists. The state metric updates of block 910 are carried out in any desired convenient order once all the needed updated extrinsic information has been received at block 905. Once the block 910 has completed, all of the extrinsic information elements can be updated in accordance with IRCC SISO decoding in any order. Because the CI-2 inverse permutation function is the inverse of the CI-2 permutation function, the same set of parallel transfer cycles can be used in the reverse direction. With the parallel transfer cycles arranged in this way, and with any needed buffering being performed in the output buffers 675, 685, the E-REG register banks can be used to handle the bi-directional data transfer and storage functions of both the I-REG and O-REG register banks used in the system 600.

The present invention also contemplates an alternative embodiment of the computer aided design method 700 for use with the system 1000. This alternative embodiment of the method 700 is preferably programmed to optimize the interconnection network 670, 680 and/or the output buffering requirements 675, 685, much as the method 700 was used to optimize or improve parallel data transfer cycles on the system 600. Start with step 705 where a CI-2 constrained interleaver design matrix is determined using the CI-2 design rules as discussed above and in the prior art. Control passes to block 710 which makes an initial assignment of codewords to processors, for example, in their natural order by consecutively assigning codewords to the CW_{N} matrix in column major order. Other initial assignments of codewords to the CW_{N} matrix can be also used. For example, since the first step of the CI-2 design matrix design rules is to randomly assign codewords to rows of the CI₂ matrix, the initial assignments of codewords to the columns of the CW_{N} matrix can be based upon the pseudorandom assignment of codewords to rows of the CI₂ matrix. The objective of block 710 is to assign the codewords of the outer code B to columns of the CW_{N} matrix in such a way as to reduce or minimize a measure related to the passage of the data elements involved in a corresponding sequence of parallel transfer cycles that are used to implement one complete iteration of CTBC code SISO decoding.

Once the CI₂ matrix and the CW_{N} matrix are fixed as per 705, 710, all of the above mentioned nK number of linked lists of metadata can be generated. At block 715 these nK linked lists are then stepped through, one at a time and the resulting parallel transfer cycles produced thereby are analyzed in a loop 715,720,725. Different values of the initial linked list seed element, CW_{N}(i_{row}^{(j)}, j) can also be stepped through and considered by the computer aided design software. For a given initial seed value, CW_{N}(i_{row}^{(j)},j) by the time an appropriate set of nK linked lists have been analyzed in terms of the interconnection network requirements and the output buffering requirements as discussed above in connection with the method 700, control passes to block 735 where the traffic pattern and/or metrics related thereto are recorded.

As discussed in connection with the other embodiments of the method 700 above, the block 740 can accept a given solution or can decide to continue to look for a better solution. In a preferred embodiment, if the solution is not acceptable, but a candidate solution is close enough, the block 740 will analyze where the trouble spots in a candidate traffic pattern are occurring and attempt to avoid them by applying the above discussed sequence of bit swaps to apply CI₂ matrix a transform T^{(1, 2)}:CI₂⁽¹⁾→CI₂⁽²⁾ so that the trouble spots can be avoided or a measure of connection or buffering can be reduced. Similarly, as control passes to block 710, the codeword assignments can be readjusted in order to attempt to reduce any adverse traffic conditions detected in a previous pass through block 725 when it analyzed the candidate mapping.

Referring now to FIG. 11, a general method of processing 1100 is provided for carrying out CTBC code SISO iterative decoding in parallel in accordance with an aspect of the present invention. The method 1100 can be carried out on any of the systems 600, 800, and 1000, or any of their equivalents, alternative embodiments or variants. In general any parallel processing system that carries out the method 1100 is within the scope of the present invention.

In the method 1100 a received signal, r(t), is received. The received signal is typically received from a channel and processed to provide a baseband representation of that signal. The received signal, r(t), represents a received version of a CTBC coded signal that has been generated and transmitted in accordance with any particular specific embodiment of FIG. 1 that can be implemented in many ways as discussed above in connection with FIG. 1. The received signal, r(t), is typically also corrupted by channel noise and in some cases channel distortion, timing and/or phase recovery jitter, polarization fluctuations, and/or other impairments. In the method 1100, the received signal, r(t), is processed at block 1105 in order to compute a vector (or set of) of input bit metrics, rₛ, for example, as discussed above in connection with FIG. 2 at block 505 and as discussed in connection with FIG. 3. Block 1105 differs from block 505 in that block 1105 specifically breaks the vector of received signal metrics, rₛ, into M subsequences containing elements of the vector of input bit metrics, rₛ, and each of these subsequences are distributed to at least M respective processors for at least one pass of parallel subsequence decoding in accordance with IRCC SISO decoding.

Next, at block 1110, each of the M processors, Pⱼ for j=1, . . . M, performs a pass through IRCC SISO decoding on its respective subsequence of the IRCC sequence. Each IRCC subsequence is defined as the subsequence of information that is updated on each respective one of the M processors during IRCC SISO decoding. Typically, each of the IRCC subsequences corresponds to a respective updated set of extrinsic information generated during IRCC SISO decoding. Each respective IRCC subsequence seeks to converge to a decoded bit sequence that corresponds to a respective set of decoded bits related to the corresponding respective subsequence of input bit metrics sent to processor Pⱼ. It is known to those of skill in the art how to implement block 1110. For example see the Robertson, Hu and Dobkin references which provide low level detailed examples of how block 1110 can be performed using prior art methods.

Next, at block 1115, the M≦N subsequences of IRCC SISO decoding updated output information are coupled from the M processors to a parallel deinterleaver. For example, the parallel deinterleaver can be the INASL 635 in any of the systems 600, 800 and 1000, or any of the variants of the INASL discussed above. More generally, any parallel deinterleaver can be any device that deinterleaves a set of M parallel subsequences of IRCC SISO decoding updated output information. Typically the M parallel subsequences of IRCC SISO decoding updated output information correspond to updated extrinsic information output from the M parallel IRCC SISO decoding passes are performed on the M IRCC subsequences as discussed above. Block 1115 is typically implemented by having each processor, Pⱼ, send a stream of IRCC SISO decoding updated output information to a respective input port of the parallel deinterleaver. This stream is preferably sent as each processor continues to produce new IRCC SISO decoding outputs such as updated elements of extrinsic information. The parallel deinterleaver performs its parallel deinterleaving function which preferably corresponds to a CI-2 inverse permutation function. Block 1115 typically passes sets of M elements at a time from M different streams coming from the M different processors in a given parallel transfer cycle. After passing through the parallel deinterleaver, the M streams containing the IRCC SISO decoding output data are coupled to N register banks or memory locations accessible by a set of N processors. Typically, depending on the specific system architecture used to execute the method 1100, M<N or M=N. As in FIG. 3 and FIG. 10, the M processors can be the same as the N processors (605, . . . , 650). As in FIG. 8, the M processors may correspond to IRCC processors 606, . . . , 651 which are different from the N processors 605, . . . , 650. In all embodiments of the present invention, N>1. As can be seen from the specific examples provided in connection with the systems 600, 800, and 1000 of FIGS. 3, 8, and 10, the outputs from IRCC SISO decoding can be generally transmitted via a parallel deinterleaver to N target O-REG register banks or to respective equivalent or modified target memory storage areas that can hold one or more codewords worth of updated extrinsic information that was updated by the previous IRCC SISO decoding. In general, block 1115 involves passing the outputs of the IRCC SISO decoding operations performed on the M processor to N processors which will use the above described outputs of the IRCC SISO decoding operations in a subsequent pass of OBC SISO decoding. At block 1120, each of the N processors performs OBC SISO decoding on at least one codeword of the outer code B used by the associated CTBC code being SISO decoded.

At block 1125 one or more stopping criteria are checked. For example, the stopping criterion may correspond to any stopping criterion 530 as discussed above to cause CTBC code SISO iterative decoding to halt because the CTBC code SISO iterative decoding has converged and/or a set number of CTBC code SISO iterations have been performed. As also discussed above, extra ML based stopping criteria can also be checked for candidate codewords to prune out potentially erroneous solutions. If such stopping criteria are in use, then portions of blocks 1120 and 1125 occur in parallel. However, when at block 1125 the stopping criterion corresponds to the CTBC code SISO iterative decoding stopping condition 530 being met, control passes to block 1135 where a set of Lρm decoded message bits are made available for output, for example, for use by one or more higher layer communication services and/or eventually an application layer program. As discussed earlier, the outputs may be passes through the INASL 635 to an additional output port (not shown in FIGS. 3, 8 and 10) in order to collect the decoded message bits from the N processors. If the stopping condition 530 of block 1130 is not met, then another pass through IRCC SISO decoding will need to be performed so control passes from block 1125 to block 1130.

At block 1130, the N sequences of OBC SISO decoding updated output information are coupled from the N processors to a parallel interleaver. For example, the parallel interleaver can be the exemplary INASL 635 in any of the systems 600, 800 and 1000, or any of the variants of the INASL discussed above. More generally, any parallel interleaver can be any device that interleaves a set of N parallel sequences of OBC SISO decoding updated output information. Typically the N parallel subsequences of OBC SISO decoding updated output information correspond to updated extrinsic information output from the N parallel OBC SISO decoding passes performed on one or more codewords of the outer code B each. Block 1130 is typically implemented by having each respective one of the N processors send a stream of OBC SISO decoding updated output information to a respective input port of the parallel interleaver. This stream is preferably sent as each processor continues to produce new OBC SISO decoding outputs such as updated elements of extrinsic information. The parallel interleaver performs its parallel interleaving function which preferably corresponds to a CI-2 permutation function. Block 1130 typically passes sets of N elements at a time from N different streams coming from the N different processors in a given parallel transfer cycle to a set of M≦N output ports. After passing through the parallel interleaver, the N streams containing the OBC SISO decoding output data are coupled to M register banks or memory locations accessible by the set of M processors, which can be the same as or different than the set of N processors as discussed above, depending on the specific embodiment as discussed above. The M processors next use the above described outputs of the OBC SISO decoding operations in a subsequent pass of IRCC SISO decoding. As discussed above, the set of N processors can optionally compute and transmit the set of gamma values that will be needed by in subsequent IRCC SISO decoding. In such cases the gamma values are sent instead of the OBC SISO decoding updated extrinsic information, for example.

Although the present invention has been described with reference to specific embodiments, other embodiments may occur to those skilled in the art without deviating from the intended scope. First of all, the present invention contemplates that different sub portions of the above embodiments can be mixed in various ways to produce additional embodiments, or variants, and all such additional advantageous embodiments and variants are specifically contemplated herein as a part of the present invention. Alternative embodiments can be formed where the OBC encoder 405 is implemented as a non-recursive convolutional encoder, a snipped or tail-bitten recursive convolutional code, an LDPC code, or other variations of finite-length, n-bit codes. In the examples, extrinsic information related to codewords are stored in order of coded bits in the codeword, but due to the above described addressing modes that allow addresses to increment to any designated next address due to the presence of an address generation state machine, such orderings can be changed, for example to improve parallel data transfer traffic patterns through the INASL 635. While specific examples with specific component codes and frame sizes were provided, as long as the outer coded is decoded as some form of block code and the inner code is decoded as an inner recursive convolutional code, all such embodiments are contemplated by present invention. While key examples used the OTN application, it is contemplated that the present invention can be used on a (possibly on a smaller scale in some cases) for wireless and other forms of channels and application systems as well. While systems, methods and processes were described having whose blocks were presented using specific orderings of steps or blocks, it is to be understood that such orderings are exemplary and such orderings can be changed as long as the new ordering results in a practical functional alternative embodiment using that modified ordering. In many examples, and descriptions above, it is assumed that one pass of IRCC SISO decoding is followed by one pass of OBC SISO decoding and so on. Alternative embodiments are envisioned where multiple iterations, for example of the OBC SISO decoding are applied before allowing the IRCC SISO decoding to proceed, or vice versa. For example, in when the outer code B is an LDPC code, multiple LDPC iterations corresponding to OBC SISO decoding can be performed before passing updated extrinsic information for subsequent IRCC SISO decoding. While various mathematical process and computerized algorithms, transformations, and metadata were described using specific symbol and notations, it is understood that such symbols and notations can be changed by one of skill in the art without departing from the spirit and scope of the present invention. Hence it is noted that all such embodiments and variations are contemplated by the present invention.

While CI-2 permutation functions are used in the exemplary embodiments, other permutation functions such as CI-3 permutation functions that also maintain a target MHD of a given CTBC code could optionally be used in alternative embodiments of the present invention. While parallel transfer cycles are described in the examples above as sending N elements at a time, some sequencing arrangements could be designed where less than N elements are passed during a parallel transfer cycle. Also, in certain embodiments, due to internal buffering and multistage interconnection network embodiments, N elements may not actually be passed in parallel, but may be skewed due to internal contentions, buffering and output contentions and buffering. Also, due to pipelining, several parallel transfer cycles could be executing in different stages of the INASL 635 at the same time. Internal buffering and conflicts could in some cases cause an element from a previous parallel transfer cycle to pass an element from a current parallel transfer cycle. The sequencing logic described above or tags or any other means could be programmed into the system to ensure that the data is eventually written to its target register bank location on the other side of the sequence of parallel transfer cycles. Also, while many exemplary embodiments mentioned sending updated extrinsic information through the INASL, it is recognized that other types of SISO decoding updated information could alternatively be sent in different embodiments of the present invention.

In FIG. 9 And the discussion thereof, blocks 805, 810, and 825 use an ends-to-middle-ordering. This allows half of the alpha forward recursion and half of the beta backward recursion to complete while the OBC SISO decoding updated elements of extrinsic information (or gamma values) stream in across the INASL 635 and in pipeline-parallel with OBC SISO decoding. An alternative ordering is to receive the OBC SISO decoding updated elements in left-to-right ordering. In this embodiment all of the alpha forward recursion is completed while the OBC SISO decoding updated elements stream in. Then the full backward recursion is performed. This involves the same waiting time as the ends-to-middle approach discussed above. Another alternative ordering is to fill the I-REG register banks in a right-to-left ordering. In this alternative embodiment, the backward beta recursion is computed while the OBC SISO decoding updated elements stream in. Then the full backward recursion is performed. This also involves the same waiting time as the ends-to-middle approach discussed above. Independent of the ordering in which the OBC SISO decoding output information elements stream in, if the OBC SISO decoding output information elements stream in slower that it takes to perform an alpha or a beta update, IRCC SISO decoding extrinsic information elements can be computed at any point where the alpha, beta and gamma have already been computed.

Also, as indicated in U.S. Pat. No. 8,537,919 and U.S. Pat. No. 8,532,209, the mapper 420 can alternatively use bit interleaved coded modulation (BICM). For example, a different mapping policy (other than the standard Gray coding) along with a second interleaver such as a custom tailored constrained interleaver can be included to increase the interleaver gain and/or the minimum Euclidean distance of the CTBC encoded signal, thereby further improving performance. In a sense, the presence of a BICM mapper 420 will typically cause another level of interleaving to be added. The present invention contemplates using any of the apparatus, systems, and methods described herein to implement the BICM decoding portion of the CTBC code SISO decoding process. For example, in the system 600, the processors 605, . . . , 650 (and/or the processors 606, . . . , 651 of the system 800) could additionally be programmed to perform BICM decoding and the INASL 635 could be further sequenced to cause the data paths in the INASL to implement parallel deinterleaving and parallel interleaving associated with the BICM portion of the CTBC code SISO iterative decoding, for embodiments that use BICM in the mapper 420. Similarly, the method 1100 could be augmented to perform BICM decoding, interleaving, and deinterleaving, followed by the method 1100 as illustrated in FIG. 11.

U.S. Pat. No. 8,537,919 and U.S. Pat. No. 8,532,209 often use the modulator of the BICM scheme to replace the inner code in turbo product code type embodiments. However, these patents generally teach that an inner code can be replaced by a BICM (i.e., a modulator). Also, U.S. Pat. No. 8,532,209 teaches that two inner codes can be concatenated together to form a double concatenation. Therefore U.S. Pat. No. 8,532,209 teaches that the CTBC code can be followed by a modulator instead a second IRCC via a second interleaver. This is the same as simply stating that the mapper 420 performs its mapping function in accordance with selected BICM mapping policy. In such embodiments, the systems 600, 800, and 1000 and the method 1100 can be programmed and/or sequenced using hardware description language state machines and the like to perform both BICM decoding operations in conjunction with CTBC SISO iterative decoding. For example, if the mapper 420 is implemented as a BICM mapper which has its own BICM interleaver integrated within the mapper 420, the updated extrinsic information from each pass of IRCC SISO decoding will need to be post-processed with an extra step.

To understand this extra step, consider an embodiment of the mapper 420 that maps its input CTBC coded bit stream to a 16-QAM constellation via a BICM interleaver according to a selected BICM mapper. This will cause sets of four coded bits to be mapped to each 16-QAM constellation point. However, due to the BICM interleaving the bit metrics and input signal metrics as discussed above in connection with the calculation of the elements of the vector (or sequence) rₛ of bit metrics or more generally input signal metrics, will be permuted by the BICM mapper such that individual bits associated with a given input symbol will be distributed to different processors, for example, of the processors 605, . . . , 650 in FIG. 3. The extra step will require that the extrinsic information updated during IRCC SISO decoding will need to be updated again to take into account the BICM mapping. For example, suppose that the four bits associated with a given 16-QAM received signal point get mapped to four different ones of the processors 605, . . . , 650 in FIG. 3. Then the INASL may be used with a multiported memory bank such as one or more extra as yet unused (or vacant and reused) memory locations in the I-REG and/or O-REG register banks to collect up the four bits worth of extrinsic information associated with the given input signal point. Once these elements of extrinsic information are collected, they can be compared with the received signal metrics associated with the 16-QAM received signal point and corrected/updated in accordance the received signal metrics and BICM decoding.

Hence it is to be understood that U.S. Pat. No. 8,537,919 and U.S. Pat. No. 8,532,209 were incorporated by reference herein to additionally disclose the full details of all of the alternative embodiments provided in those patents. Using any of these incorporated by reference details together with the disclosure of the present invention, the parallel processing systems 600,800,1000 or any of their variants or equivalents can readily use the available hardware, but with modified instruction or control sequences.

Hence it is to be understood that the present invention is to be defined by the claims herein, and elements of the specific examples provided above should not be read into the claims. Each claim in this patent application and any continuation, divisional, reissue or foreign filing is to be used to define the meets and bounds of the present invention, not the specific details of specific examples or exemplary embodiments.

What we claim is:

1. A method for use in a parallel processing system, the method comprising:
distributing M respective subsequences of digitized received signal input information elements to M respective local memory banks, wherein each of the M respective local memory banks is coupled to a respective one of a set of M processors, wherein M is an integer and M>1;
at each respective one of the M processors, performing, a respective pass of inner recursive convolutional code (IRCC) soft input soft output (SISO) decoding (IRCC SISO decoding) to produce a respective subsequence of IRCC SISO decoding output information elements;
performing parallel constrained deinterleaving in order to distribute, in parallel, a plurality of the IRCC SISO decoding output information elements to a set of respective target memory locations located in respective target ones of a set of N multiport memory banks, wherein N is an integer and N≧M, wherein the plurality of IRCC SISO decoding output information elements include IRCC SISO decoding output information elements that were generated in a plurality of different ones of the M processors;
at each respective one of the N processors, performing a respective pass of outer block code (OBC) SISO decoding (OBC SISO decoding) to produce a respective subsequence of OBC SISO decoding output information elements associated with one or more codewords of an outer block code, B;
in the event that a stopping criterion has not been met, performing parallel constrained interleaving in order to distribute, in parallel, a plurality of OBC SISO decoding output information elements to a set of respective target memory locations located in respective target ones of a set of M multiport memory banks, and repeating the above recited actions, starting with the action of performing IRCC SISO decoding at each respective one of the M processors, until the stopping criterion is met, wherein the plurality of OBC SISO decoding output information elements include OBC SISO decoding output information elements that were generated in a plurality of different ones of the N processors; and
in the event that the stopping criterion has been met, outputting a set of decoded message bits;
wherein the M processors perform their respective passes of IRCC SISO decoding substantially in parallel with each other, and the N processors perform their respective passes of OBC SISO decoding substantially in parallel with each other;
wherein the M processors are a member of the group consisting of M processors that are different from the N processors, and M processors that are a subset of the N processors;
wherein the M multiport memory banks are a member of the group consisting of multiport memory banks different from the N multiport memory banks, and M multiport memory banks that are a subset of the N multiport memory banks, and
wherein the stopping criterion is a member of the group consisting of performing a fixed number of the updating operations, and determining that a convergence criterion has been met.

2. The method of claim 1, wherein M=N.

3. The method of claim 2, wherein the M processors are a subset of the N processors, and therefore the M processors are the same as the N processors.

4. The method of claim 2, wherein the M multiport memory banks are a subset of the N multiport memory banks, and therefore the M multiported memory banks are the same as the N multiported memory banks.

5. The method of claim 4, wherein the M=N multiported memory banks correspond to a set of E-REG register banks.

6. The method of claim 2, wherein the M multiported memory banks correspond to a set of I-REG register banks are the N multiported memory banks correspond to a set of O-REG register banks.

7. The method of claim 1, wherein M<N.

8. The method of claim 7, wherein the M processors that are different from the N processors.

9. The method of claim 1, wherein distributing M respective subsequences of elements of received signal input information to the M respective local memory banks is performed via at least one multiported memory bank accessible to the respective processor to which the local memory bank is coupled.

10. The method of claim 1, wherein the M respective local memory banks are implemented as multiported memory banks and the distributing M respective subsequences of elements of received signal input information to the M respective local memory banks is performed via respective ports associated with each of the M respective local memory banks.

11. The method of claim 1, further comprising coupling from each respective one of the M multiported memory banks the respective subsequence of IRCC SISO decoding output information elements to a respective input port configured to receive inputs for parallel constrained deinterleaving.

12. The method of claim 1, wherein each IRCC SISO decoding output information element is associated with an updated extrinsic information element updated during the respective pass of IRCC SISO decoding.

13. The method of claim 1, wherein each IRCC SISO decoding output information element is an updated extrinsic information element updated during the respective pass of IRCC SISO decoding.

14. The method of claim 1, wherein each respective one of the N multiport memory banks has at least a first port configured to receive the IRCC SISO decoding output information elements from the constrained deinterleaving, and a second port that is coupled to a respective one of a set of N processors.

15. The method of claim 1, wherein each OBC SISO decoding output information element is associated with an extrinsic information element updated during the respective pass of OBC SISO decoding.

16. The method of claim 1, wherein each OBC SISO decoding output information element is an extrinsic information element updated during the respective pass of OBC SISO decoding.

17. The method of claim 1, wherein each OBC SISO decoding output information element is a gamma value to be used in subsequent IRCC SISO decoding, and the gamma value is computed as an addition of an extrinsic information element updated during the respective pass of OBC SISO decoding plus a received signal metric.

18. The method of claim 1, wherein each respective one of the M multiport memory banks has at least a first port configured to receive OBC SISO decoding output information elements from the constrained deinterleaving, and a second port that coupled to a respective one of a set of N processors.

19. The method of claim 1, wherein the parallel constrained deinterleaving and the parallel constrained interleaving are carried out on a interconnection network and address sequencing logic (INASL) subsystem.

20. A parallel processing system, comprising:
an interconnection network and address sequencing logic unit (INASL);
a set of N processors, configured perform processing operations in parallel with each other;
a set of N local memory banks, each coupled to be accessed by a respective one of the N processors;
a first set of N multiported memory banks (I-REG register banks), each coupled to be accessed by a respective one of the N processors and each coupled to a port of the INASL;
a second set of N multiported memory banks (O-REG register banks), each coupled to be accessed by a respective one of the N processors and each coupled to a port of the INASL;
an input signal distribution unit coupled to receive digitized information related to an input signal, r(t), that has been encoded according to a constrained turbo block convolutional (CTBC) code, received from a communication channel, and demodulated, wherein the input signal distribution unit is configured to distribute N respective subsequences of digitized received signal input information elements to the N respective local memory banks;
a first sequence of control inputs operative to cause to be performed at each respective one of the N processors, a pass of inner recursive convolutional code (IRCC) soft input soft output (SISO) decoding (IRCC SISO decoding) to produce a respective subsequence of IRCC SISO decoding output information elements;
a second sequence of control inputs operative to cause to be performed constrained deinterleaving in order to distribute, in parallel, a plurality of the IRCC SISO decoding output information elements to a set of respective target memory locations located in respective target ones of the set of N O-REG register banks, wherein each respective one of the N O-REG register banks has at least a first port configured to receive the IRCC SISO decoding output information elements from the constrained deinterleaving, and a second port that is coupled to a respective one of the set of N processors;
a third sequence of control inputs operative to cause to be performed at each respective one of the N processors, a pass of outer block code (OBC) soft input soft output (SISO) decoding (OBC SISO decoding) to produce a respective subsequence of OBC SISO decoding output information elements associated with one or more codewords of an outer block code, B;
a fourth sequence of control inputs operative to cause to be performed, in the event that a stopping criterion has not been met, parallel constrained interleaving in order to distribute, in parallel, plurality of the OBC SISO decoding output information elements to a set of respective target memory locations located in respective target ones of a set of N I-REG register banks, wherein each respective one of the N I-REG register banks has at least a first port configured to receive OBC SISO decoding output information elements from the constrained deinterleaving, and a second port that coupled to a respective one of the set of N processors, and repeating the above recited actions, starting with the action of performing IRCC SISO decoding at each respective one of the M processors, until the stopping criterion is met; and
a fifth sequence of control inputs operative to cause to be performed, in the event that the stopping criterion has been met, a frame of decoded message bits to be coupled to one or more output ports;
wherein the N processors perform their respective passes of IRCC SISO decoding substantially in parallel with each other, and the N processors perform their respective passes of OBC SISO decoding operations in parallel with each other; and
wherein the stopping criterion is a member of the group consisting of performing a fixed number of the updating operations, and determining that a convergence criterion has been met.
